(19) United States
(12) Patent Application Publication
(10) Pub. No.: US 2025/0366095 A1
(43) Pub. Date: Nov. 27, 2025

(54) SEMICONDUCTOR DEVICE AND METHOD FOR MANUFACTURING THE SAME

(71) Applicant: Taiwan Semiconductor Manufacturing Company, Ltd., Hsinchu (TW)

(72) Inventors: Kuan-Ting PAN, Hsinchu (TW); Kuo-Cheng CHIANG, Hsinchu (TW); Chih-Hao WANG, Hsinchu (TW)

(21) Appl. No.: 19/286,970

(22) Filed: Jul. 31, 2025

Related U.S. Application Data
(63) Continuation of application No. 18/338,051, filed on Jun. 20, 2023.

(51) Int. Cl. H10D 62/10; H10D 30/01; H10D 30/43; H10D 30/67; H10D 64/01; H10D 84/01; H10D 84/03; H10D 84/85

(52) U.S. Cl. CPC H10D 62/121; H10D 30/014; H10D 30/43; H10D 30/6735; H10D 30/6757; H10D 64/017; H10D 84/0167; H10D 84/0188; H10D 84/038; H10D 84/85

(57) ABSTRACT

A semiconductor device includes a semiconductor substrate, a first semiconductor structure, a second semiconductor structure, a third semiconductor structure, a dielectric wall, and a first isolation feature. The first semiconductor structure, the second semiconductor structure and the third semiconductor structure are disposed on the semiconductor substrate. The first semiconductor structure is disposed between the second semiconductor structure and the third semiconductor structure. The dielectric wall is disposed on the semiconductor substrate and is connected between the first semiconductor structure and the second semiconductor structure. The first isolation feature is disposed between the first semiconductor structure and the third semiconductor structure, and extends into the semiconductor substrate.

### CROSS-REFERENCE TO RELATED APPLICATIONS

This application is a continuation of U.S. patent application Ser. No. 18/338,051 filed Jun. 20, 2023, the entire disclosure of which is incorporated herein by reference.

### BACKGROUND

With the dramatic advancement of the semiconductor manufacturing technology, a semiconductor integrated circuit (IC) chip can be scaled down with an increased device functional density (i.e., the number of electrical devices per chip area). For example, in a semiconductor IC chip with three-dimensional transistors, FEOL (front-end-of-line) metal gate (MG) structure is being cut to obtain a plurality of metal gate portions, and each of the metal gate portions can be used in an individual transistor. Nevertheless, in order to further enhance the power efficiency of a semiconductor IC chip, improvement of the electrical characteristics thereof is required, such as lowering chip capacitance for reducing resistance-capacitance (RC) time delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2 to 24 are schematic views illustrating some intermediate stages of the method as depicted in FIGS. 1A and 1B in accordance with some embodiments.

FIG. 25 is a schematic view illustrating a partially enlarged portion of a semiconductor device in accordance with some embodiments.

FIG. 26 is a schematic view illustrating a partially enlarged portion of a semiconductor device in accordance with some embodiments.

FIGS. 27A to 27C are schematic views illustrating a semiconductor device in accordance with some embodiments.

FIG. 28 is a schematic view illustrating a semiconductor device in accordance with some embodiments.

FIGS. 29A to 35 are schematic views illustrating intermediate stages of a method for manufacturing a semiconductor device in accordance with some embodiments.

FIGS. 36A and 36B are schematic views illustrating a semiconductor device in accordance with some embodiments.

FIG. 37 is a schematic view illustrating a semiconductor device in accordance with some embodiments.

FIGS. 38 to 40 are schematic views illustrating a semiconductor device in accordance with some embodiments.

FIGS. 41 to 43 are schematic views illustrating a semiconductor device.

FIGS. 44 to 47 are schematic views illustrating a portion of a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Nowadays, nanosheet semiconductor devices (e.g., nanosheet field-effect transistors (FETs)) are applied in various fields, such as consumer electrical products. In order to meet various application needs, the semiconductor industry strives to improve device performance of the nanosheet semiconductor devices. However, improvement of the device performance of the nanosheet semiconductor devices faces some challenges. For example, there is a restriction on reduction of a spacing between two oxide-definition regions in a nanosheet semiconductor device because a certain size of metal gate endcap portions (i.e., portions of a metal gate structure defined between a plurality of channel features and an isolation portion that is disposed in the metal gate structure) is required for meeting requirements of device performance (e.g., a threshold voltage (Vₜₕ) or the like) of the nanosheet semiconductor device. For example, the isolation portion is formed to cut the metal gate structure, and formation of the isolation portion may be affected by certain fabrication process variations (e.g., overlay shift and critical dimension variation in photolithography process or the like), resulting in a reduction of size of the metal gate endcap portions, and further affecting the Vₜₕ of the nanosheet semiconductor device. In addition, the nanosheet semiconductor devices still have a resistance-capacitance (RC) time delay issue to be solved. Therefore, in order to improve device performance of the nanosheet semiconductor devices, these challenges need to be overcome.

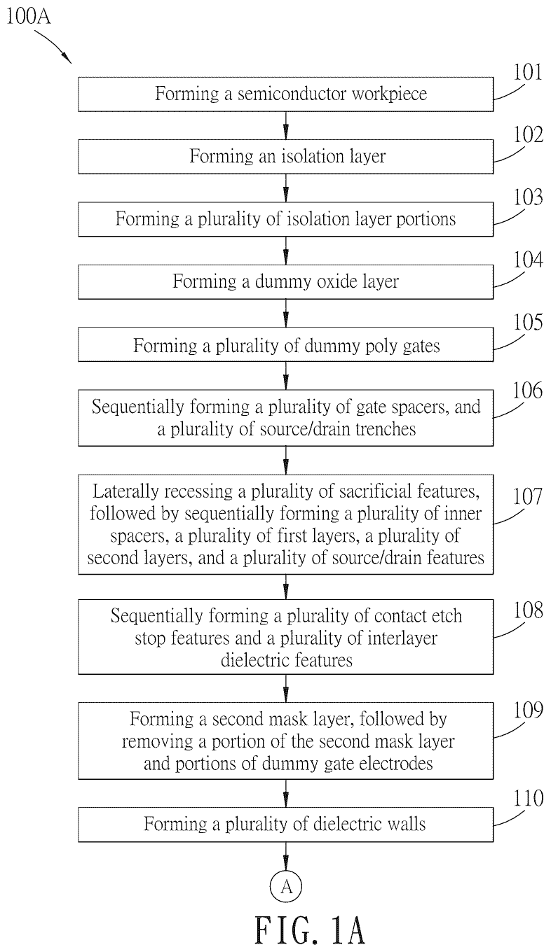

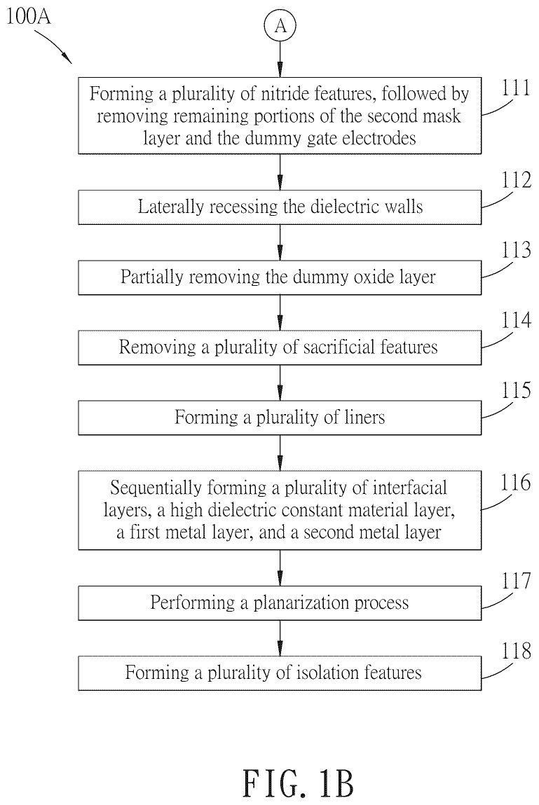

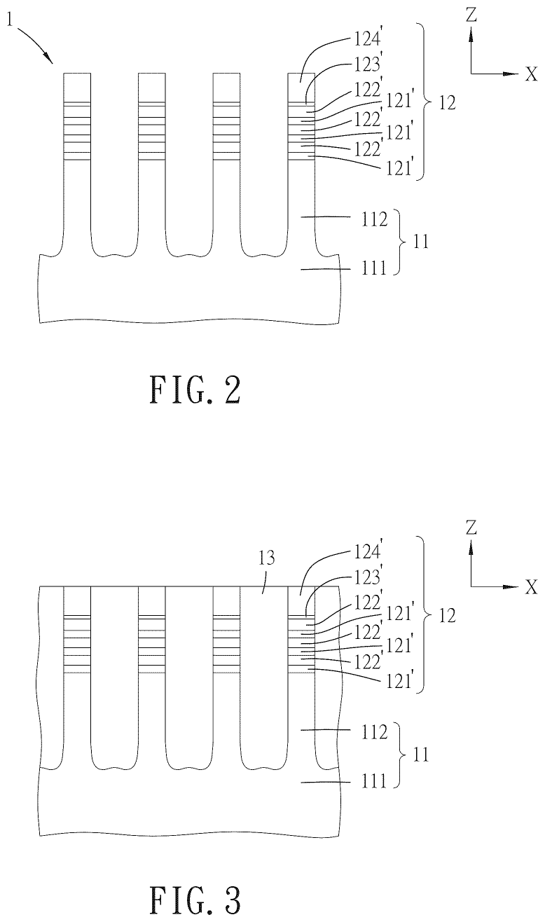

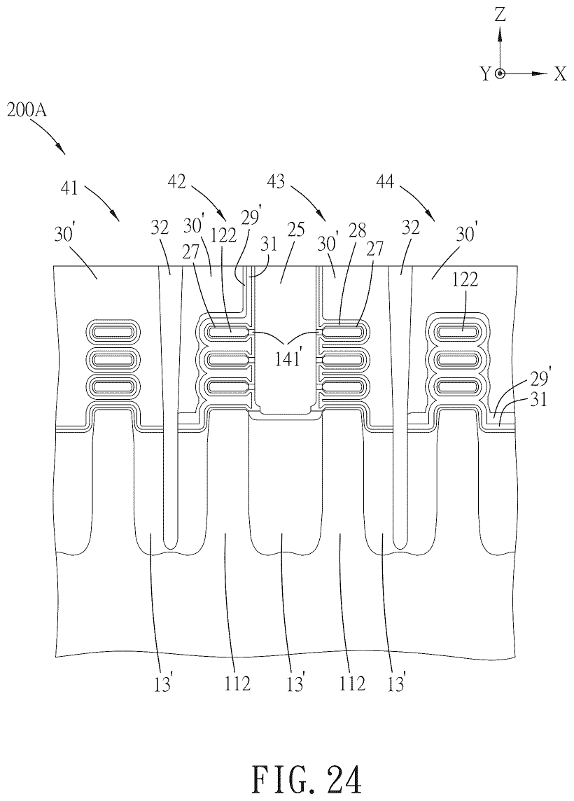

The present disclosure is directed to a semiconductor device and a method for manufacturing the same. FIGS. 1A and 1B are flow diagrams illustrating a method 100A for manufacturing a semiconductor device 200A shown in FIG. 24 in accordance with some embodiments. FIGS. 2 to 24 illustrate schematic views of some intermediate stages of the method 100A. Some portions may be omitted in FIGS. 2 to 24 for the sake of brevity. Additional steps can be provided before, after or during the method 100A, and some of the steps described herein may be replaced by other steps or be eliminated.

Referring to FIG. 1A and the example illustrated in FIG. 2, the method 100A begins at step 101, where a semiconductor workpiece 1 is provided. The semiconductor workpiece 1 includes a semiconductor substrate 11 and a plurality of fin structures 12.

The semiconductor substrate 11 may include, but are not limited to, an elemental semiconductor or a compound semiconductor. The elemental semiconductor includes a single species of atoms, such as silicon (Si) or germanium (Ge) from column XIV of the periodic table, and may be crystalline, polycrystalline, or amorphous in structure. Other suitable materials for the elemental semiconductor are within the contemplated scope of the present disclosure. The compound semiconductor includes two or more elements, and examples thereof may include, but are not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable materials for the compound semiconductor are within the contemplated scope of the present disclosure. The compound semiconductor may have a gradient feature in which the compositional ratio thereof changes from one location to another location in the compound semiconductor. The compound semiconductor may be formed over a silicon substrate and may be strained. In some embodiments, the semiconductor substrate 11 may include a multilayer compound semiconductor structure. In some embodiments, the semiconductor substrate 11 may include a base portion 111 and a plurality of fin portions 112 that are disposed on the base portion 111 in a Z direction and that are spaced apart from each other by trenches in an X direction transverse to the Z direction.

The fin structures 12 are respectively disposed on the fin portions 112 of the semiconductor substrate 11. Each of the fin structures 12 includes a nanosheet stack, an oxide layer portion 123′, and a mask layer portion 124′ that are sequentially disposed on a corresponding one of the fin portions 112 of the semiconductor substrate 11. The nanosheet stack includes a plurality of sacrificial layer portions 121′ and a plurality of channel layer portions 122′ which are alternately stacked over one another. The sacrificial layer portions 121′ may include silicon germanium (SiGe). The channel layer portions 122′ may include silicon (Si). The oxide layer portion 123′ is disposed on the nanosheet stack opposite to the semiconductor substrate 11, and may include silicon oxide. The mask layer portion 124′ is disposed on the oxide layer portion 123′ opposite to the nanosheet stack, and may be made of a nitride-based material (for example, silicon nitride). Other suitable materials for each of the sacrificial layer portions 121′, the channel layer portions 122′, the oxide layer portion 123′, and the mask layer portion 124′ are within the contemplated scope of the present disclosure.

In some embodiments, the semiconductor workpiece 1 is obtained by sequentially forming a semiconductor stack (not shown), an oxide layer (not shown) and a mask layer (not shown) over the semiconductor substrate 11, followed by conducting a photolithography process to pattern the semiconductor stack, the oxide layer and the mask layer, so as to obtain the semiconductor workpiece 1. In some embodiments, the semiconductor stack may include a plurality of sacrificial layers (not shown) and a plurality of channel layers (not shown) which are alternately stacked on the semiconductor substrate 11. In some embodiments, the sacrificial layers and the channel layers may be formed by a suitable deposition process, for example, but not limited to, chemical vapor deposition (CVD) (e.g., ultra-high vacuum CVD (UHV-CVD)) or other suitable deposition processes. In alternative embodiments, the sacrificial layers and the channel layers may be formed by a suitable epitaxial process, for example, but not limited to, molecular beam epitaxy (MBE) or other suitable epitaxial processes. The oxide layer may be formed by a suitable deposition process, for example, but not limited to, CVD, atomic layer deposition (ALD), or other suitable deposition processes. The mask layer may be formed by a suitable deposition process, for example, but not limited to, CVD (e.g., plasma-enhanced CVD (PECVD)), ALD (e.g., plasma-enhanced ALD (PEALD)), or other suitable deposition processes. After the photolithography process, the trenches are formed to penetrate through the mask layer, the oxide layer and the semiconductor stack, and to terminate at the base portion 111 of the semiconductor substrate 11, so as to form the sacrificial layers, the channel layers, the oxide layer and the mask layer into the sacrificial layer portions 121′, the channel layer portions 122′, the oxide layer portions 123′, and the mask layer portions 124′, respectively.

Referring to FIG. 1A and the example illustrated in FIG. 3, the method 100A then proceeds to step 102, where an isolation layer 13 is formed over the structure shown in FIG. 2. The isolation layer 13 may be made of an oxide-based material (e.g., silicon oxide), a nitride-based material (e.g., silicon nitride), or a combination thereof. Other suitable materials for the isolation layer 13 are within the contemplated scope of the present disclosure. The isolation layer 13 may be formed by a suitable deposition process, for example, but not limited to, CVD, physical vapor deposition (PVD), or other suitable deposition processes. In this step, after formation of the isolation layer 13, a planarization process (e.g., chemical mechanical polishing (CMP) or other suitable planarization processes) may be performed to remove an excess portion of the isolation layer 13.

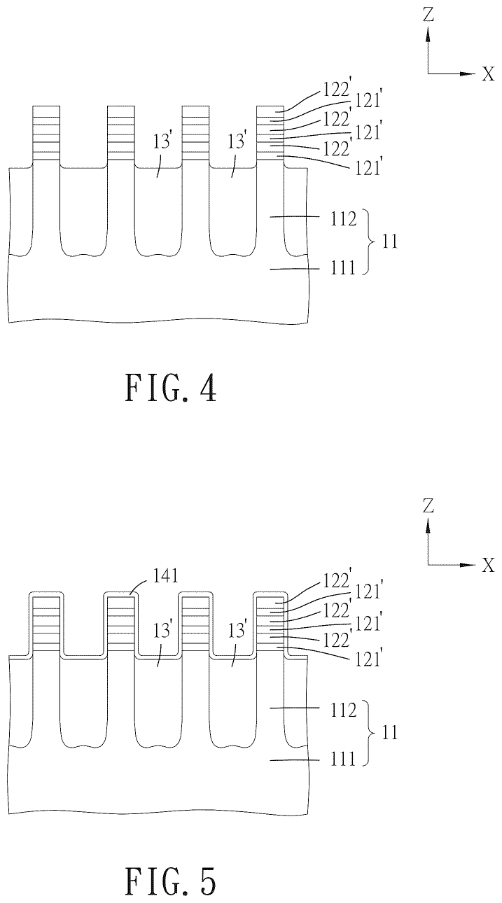

Referring to FIG. 1A and the example illustrated in FIG. 4, the method 100A then proceeds to step 103, where the oxide layer portions 123′ and the mask layer portions 124′ are removed and the isolation layer 13 is recessed by a suitable etching process (e.g., dry etching, wet etching or a combination thereof), so as to form a plurality of isolation layer portions 13′. Each of the isolation layer portions 13′ is disposed on the base portion 111 of the semiconductor substrate 11, and in a corresponding one of the trenches. Two adjacent ones of the isolation layer portions 13′ are located at two opposite sides (e.g., opposite to each other in the X direction) of a corresponding one of the fin portions 112 of the semiconductor substrate 11, so as to separate and isolate the nanosheet stacks from each other. Each of the nanosheet stacks includes the sacrificial layer portions 121′ and the channel layer portions 122′ which are alternately stacked over one another. In some embodiments, each of the isolation layer portions 13′ may be a portion of a shallow trench isolation (STI), a deep trench isolation (DTI), or other suitable structures.

Referring to FIG. 1A and the example illustrated in FIG. 5, the method 100A then proceeds to step 104, where a dummy oxide layer 141 is conformally formed over the structure shown in FIG. 4. The dummy oxide layer 141 may include silicon oxide. Other suitable materials for the dummy oxide layer 141 are within the contemplated scope of the present disclosure. The dummy oxide layer 141 may be formed by a suitable deposition process, for example, but not limited to, CVD, ALD, or other suitable deposition processes.

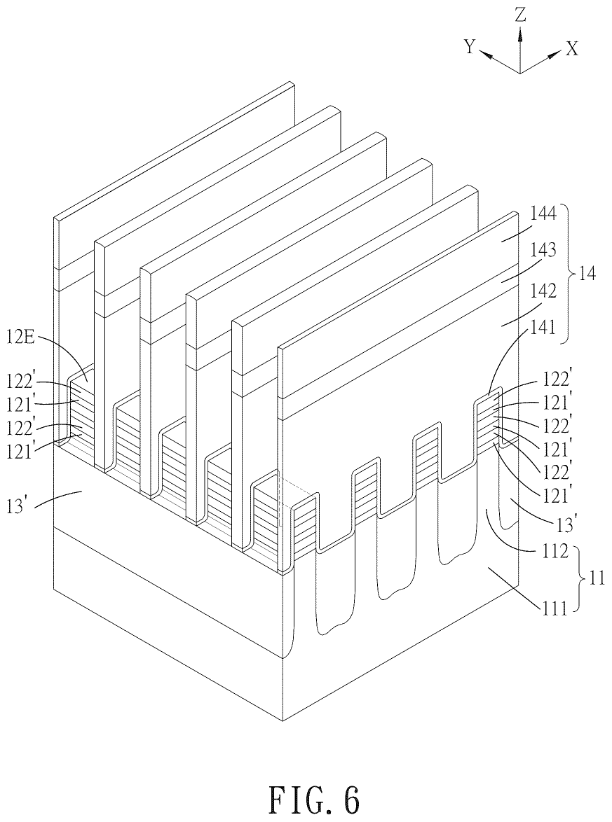

Referring to FIG. 1A and the example illustrated in FIG. 6, the method 100A then proceeds to step 105, where a plurality of dummy poly gates 14 are formed on the structure shown in FIG. 5. Each of the dummy poly gates 14 may include a dummy gate electrode 142, a polish stop layer 143, and a first mask layer 144. In some embodiments, the dummy oxide layer 141 may serve as a dummy gate dielectric of each of the dummy poly gates 14. Step 105 may be performed by sequentially depositing the respective material layers for the dummy gate electrodes 142, the polish stop layers 143 and the first mask layers 144 on the structure shown in FIG. 5, followed by conducting a photolithography process to pattern the respective material layers for the dummy gate electrodes 142, the polish stop layers 143 and the first mask layers 144, so as to form the dummy gate electrodes 142, the polish stop layers 143 and the first mask layers 144. The dummy poly gates 14 are spaced apart from each other along a Y direction transverse to the X and Z directions. The dummy gate electrode 142 is disposed on the dummy oxide layer 141. The dummy gate electrode 142 may include polysilicon. Other suitable materials for the dummy gate electrode 142 are within the contemplated scope of the present disclosure. In each of the dummy poly gates 14, the polish stop layer 143 is disposed on the dummy gate electrode 142 opposite to the dummy oxide layer 141. The polish stop layer 143 may include silicon nitride. Other suitable materials for the polish stop layer 143 are within the contemplated scope of the present disclosure. In each of the dummy poly gates 14, the first mask layer 144 is disposed on the polish stop layer 143 opposite to the dummy gate electrode 142. The first mask layer 144 may include silicon oxide. Other suitable materials for the first mask layer 144 are within the contemplated scope of the present disclosure. After this step, a plurality of exposed regions 12E are formed. Each of the exposed regions 12E is located between two adjacent ones of the dummy poly gates 14.

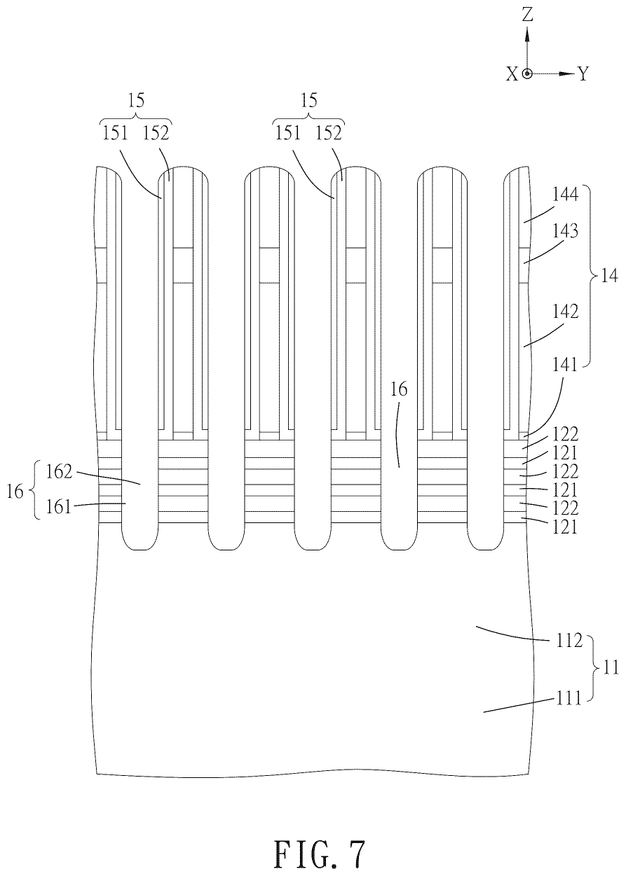

Referring to FIG. 1A and the example illustrated in FIG. 7, the method 100A then proceeds to step 106, where a plurality of gate spacers 15 are formed on the structure shown in FIG. 6, followed by recessing the exposed regions 12E (see FIG. 6), so as to form a plurality of source/drain trenches 16. Step 106 may include sub-steps 1061 and 1062.

In sub-step 1061, two spacer material layers for forming the gate spacers 15 are sequentially deposited on the dummy poly gates 14 and the exposed regions 12E (see FIG. 6) by a suitable deposition process, for example, but not limited to, CVD, ALD, or other suitable deposition processes, followed by an anisotropic dry etching process until portions of the spacer material layers, which are respectively formed on the exposed regions 12E and an upper surface of each of the dummy poly gates 14, are removed such that remaining portions of the spacer material layers serve as the gate spacers 15. The spacer material layers for forming the gate spacers 15 may include, for example, but not limited to, silicon oxide, silicon nitride, silicon oxynitride, silicon carbon nitride, silicon oxycarbonnitride, or low dielectric constant (k) materials. Other suitable materials for the gate spacers 15 are within the contemplated scope of the present disclosure. Each pair of the gate spacers 15 are respectively formed at two opposite sides of a corresponding one of the dummy poly gates 14 in the Y direction. In some embodiments, each of the gate spacers 15 may be formed as a single layer structure or a multi-layered structure (for example, but not limited to, a two-layered structure). In some embodiments, when each of the gate spacers 15 is formed as the two-layered structure, each of the gate spacers 15 may include an outer part 151 and an inner part 152 disposed between a corresponding one of the dummy poly gates 14 and the outer part 151.

In sub-step 1062, the exposed regions 12E (see FIG. 6) are recessed by a suitable etching process, for example, but not limited to, dry etching, wet etching, other suitable etching processes, or combinations thereof, so as to form the source/drain trenches 16 that are spaced apart from each other in the Y direction. After sub-step 1062, the sacrificial layer portions 121′ and the channel layer portions 122′ (see FIG. 6) are respectively patterned into sacrificial features 121 and channel features 122.

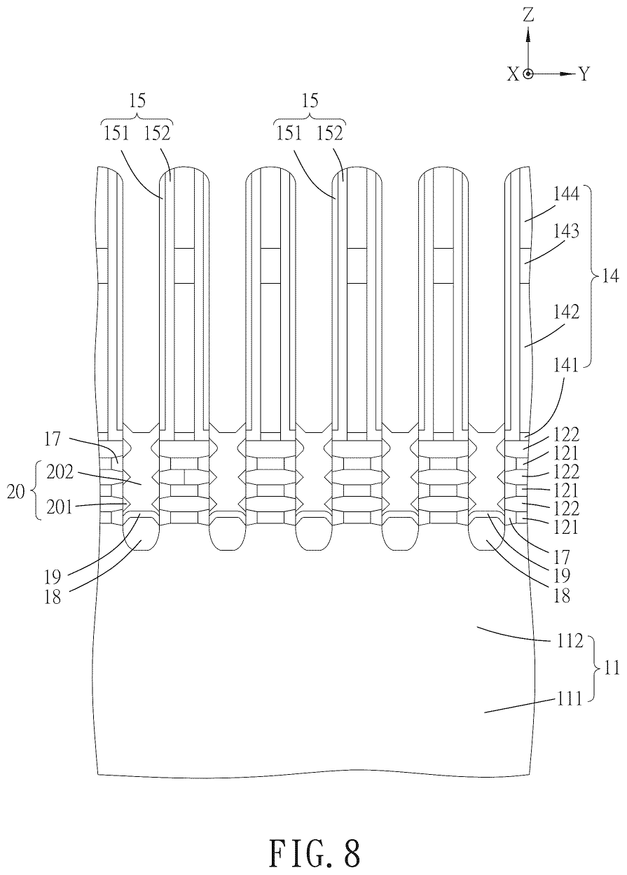

Referring to FIG. 1A and the example illustrated in FIG. 8, the method 100A then proceeds to step 107, where the sacrificial features 121 are laterally recessed, followed by sequentially forming a plurality of inner spacers 17, a plurality of first layers 18, a plurality of second layers 19, and a plurality of source/drain features 20. Step 107 includes sub-steps 1071 to 1075.

In sub-step 1071, the sacrificial features 121 are laterally recessed by an isotropic etching process, for example, but not limited to, wet etching process or other suitable etching processes to remove side portions of the sacrificial features 121 based on a relatively high etching selectivity of the sacrificial features 121 with respect to the channel features 122, so as to form a plurality of lateral recesses (not shown).

In sub-step 1072, the inner spacers 17 are formed in the lateral recesses. Sub-step 1072 may be performed by conformally depositing an inner spacer material layer (not shown) on the dummy poly gates 14 and the gate spacers 15 and in the source/drain trenches 16 (see FIG. 7) to fill the lateral recesses, followed by isotropically etching the inner spacer material layer, so as to form the inner spacers 17 in the lateral recesses. Each pair of the inner spacers 17 laterally covers a corresponding one of the sacrificial features 121. The inner spacer material layer may be formed by a suitable deposition process, for example, but not limited to, CVD, PECVD, PVD, ALD, PEALD, or other suitable deposition processes. The inner spacer material layer may include, for example, but not limited to, silicon oxide, silicon nitride, silicon oxycarbide, silicon oxynitride, silicon carbon nitride, silicon oxycarbonitride, low-k materials, or combinations thereof. Other suitable materials for the inner spacers 17 are within the contemplated scope of the present disclosure. The isotropic etching process may be a dry isotropic etching process, a wet isotropic etching process, or a combination thereof.

In sub-step 1073, the first layers 18 are respectively formed in lower trench portions 161 of the source/drain trenches 16 (see FIG. 7). The first layers 18 may be made of a semiconductor material, for example, but not limited to, silicon (Si). The first layers 18 may be formed by, for example, but not limited to, a deposition process (e.g., CVD), an epitaxial growth process (e.g., MBE), an epitaxial deposition/partial etch process (e.g., cyclic deposition-etch (CDE) process), or a selective epitaxial growth (SEG) process.

In sub-step 1074, the second layers 19 are respectively formed on the first layers 18 in the source/drain trenches 16. Sub-step 1074 may involve depositing a dielectric material layer for forming the second layers 19 in the source/drain trenches 16 and on the other structures by a suitable deposition process, for example, but not limited to, CVD, ALD, or other suitable deposition processes, and then removing excess portions of the dielectric material layer for forming the second layers 19 by a suitable etching process, for example, but not limited to, wet etching, dry etching, other suitable etching processes, or combinations thereof, such that remaining portions of the dielectric material layer serve as the second layers 19 which are respectively formed on the first layers 18 in the source/drain trenches 16. The dielectric material layer for forming the second layers 19 may include silicon oxide or silicon nitride. Other suitable materials for the second layers 19 are within the contemplated scope of the present disclosure. In some embodiments, the second layers 19 may be referred to as bottom dielectric isolations (BDIs).

In sub-step 1075, the source/drain features 20 are respectively formed on the second layers 19 in upper trench portions 162 of the source/drain trenches 16 (see FIG. 7). In some embodiments, each of the source/drain features 20 includes a plurality of outer regions 201 and a major region 202, and each of the outer regions 201 is disposed between a corresponding one of the channel features 122 and the major region 202. Sub-step 1075 may be performed by sequentially forming the outer regions 201 and the major region 202 in the upper trench portions 162 of the source/drain trenches 16 using an epitaxial growth technique. In some embodiments, the outer regions 201 may serve as seeding layers for forming the major region 202. In some embodiments in which the channel features 122 are made of silicon (Si), both of the outer regions 201 and the major region 202 may be made of silicon (Si). In alternative embodiments, the outer regions 201 may be made of silicon (Si) and the major region 202 may be made of silicon germanium (SiGe). In some embodiments, the first layers 18, the second layers 19, and the source/drain features 20 together serve as source/drain regions.

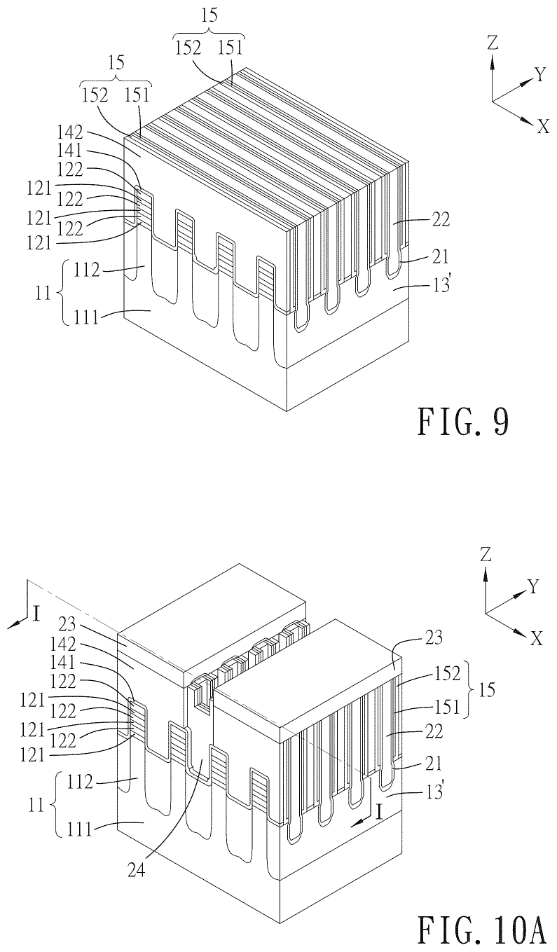

Referring to FIG. 1A and the example illustrated in FIG. 9, the method 100A then proceeds to step 108, where a plurality of contact etch stop features 21 and a plurality of interlayer dielectric (ILD) features 22 are sequentially and respectively formed on the source/drain features 20. Step 108 may include sub-steps 1081 and 1082.

In sub-step 1081, a contact etch stop layer (not shown) for forming the contact etch stop features 21 and a dielectric material layer (not shown) for forming the ILD features 22 are sequentially formed over the structure shown in FIG. 8 by a blanket deposition process, for example, but not limited to, CVD or molecular layer deposition (MLD). The contact etch stop layer for forming the contact etch stop features 21 may include, for example, but not limited to, silicon nitride, carbon-doped silicon nitride, other suitable contact etch stop materials, or combinations thereof. The dielectric material layer for forming the ILD features 22 may include, for example, but not limited to, silicon oxide, silicon nitride, silicon oxynitride, other suitable dielectric materials, or combinations thereof. Other suitable materials for forming the contact etch stop features 21 and the ILD features 22 are within the contemplated scope of the present disclosure.

In sub-step 1082, a planarization process (e.g., CMP or other suitable planarization processes) is performed to remove excess portions of the contact etch stop layer and the dielectric material layer, so as to obtain the contact etch stop features 21 and the ILD features 22. In this sub-step, the first mask layer 144 and the polish stop layer 143 of each of the dummy poly gates 14 may also be removed.

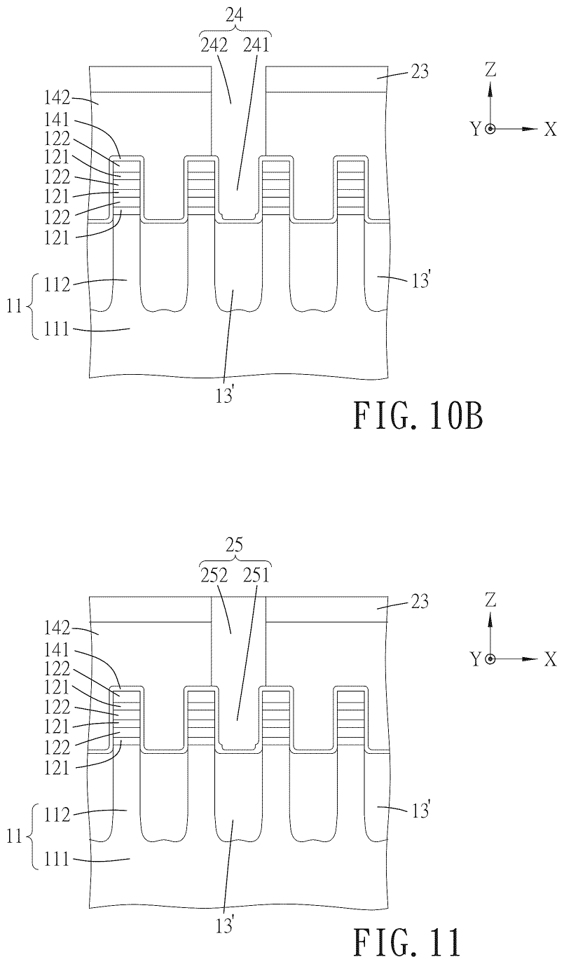

Referring to FIG. 1A and the example illustrated in FIGS. 10A and 10B, the method 100A then proceeds to step 109, where a second mask layer 23 is formed over the structure shown in FIG. 9, followed by removing a portion of the second mask layer 23 and portions of the dummy gate electrodes 142 (see FIG. 9), so as to form a plurality of wall trenches 24. FIG. 10B illustrates a cross-sectional view taken along line I-I of FIG. 10A. Step 109 may include sub-step (i) forming a mask material for the second mask layer 23 over the structure shown in FIG. 9 by a suitable deposition process (e.g., CVD or other suitable deposition processes), and sub-step (ii) removing a portion of the second mask layer 23 and portions of the dummy gate electrodes 142 by a photolithography process, which may include at least one of etching process (e.g., plasma dry etching), so as to form the wall trenches 24. The second mask layer 23 may include polysilicon, silicon nitride, silicon oxide, or combinations thereof. Other suitable materials for the second mask layer 23 are within the contemplated scope of the present disclosure. In some embodiments, the second mask layer 23 and the dummy gate electrode 142 may be made of the same material, such as polysilicon. In some embodiments, each of the wall trenches 24 may be divided into a lower trench portion 241 that is surrounded by the dummy oxide layer 141, and an upper trench portion 242 that is in spatial communication with the lower trench portion 241.

Referring to FIG. 1A and the example illustrated in FIG. 11, the method 100A then proceeds to step 110, where a plurality of dielectric walls 25 are formed in the wall trenches 24, respectively. One of the dielectric walls 25 is shown in FIG. 11. Step 110 may include sub-step (i) forming a dielectric material layer (not shown) over the structure shown in FIG. 10A or 10B by a suitable deposition process, for example, but not limited to, CVD (e.g., low-pressure CVD (LPCVD)), ALD, or other suitable deposition processes, and sub-step (ii) conducting a planarization process (e.g., CMP or other suitable planarization processes) to remove an excess portion of the dielectric material layer, so as to form the dielectric walls 25. The dielectric material layer for the dielectric walls 25 may include silicon oxide, silicon nitride, silicon carbonitride, silicon oxycarbonitride, silicon oxycarbide, or combinations thereof. Other suitable materials (e.g., k value is lower than about 7) for the dielectric walls 25 are within the contemplated scope of the present disclosure. In some embodiments, the dielectric walls 25 and the second mask layer 23 may be made of the same material. In some embodiments, the dielectric walls 25 and the dummy oxide layer 141 may be made of the same or different material. In some embodiments, the dielectric walls 25 may be formed as a multi-layered structure. In some embodiments, when the dielectric walls 25 are formed as a multi-layered structure, k value of material of the multi-layered structure may exhibit an increasing trend in a direction away from the channel features 122, which is conducive to reducing capacitance of the semiconductor structures 41, 42, 43, 44 shown in FIG. 24 (which will be described hereinafter). In some embodiments, each of the dielectric walls 25 may be divided into a lower portion 251 and an upper portion 252, where the lower portion 251 is disposed in the lower trench portion 241 (see FIG. 10B) of a corresponding one of the wall trenches 24, and the upper portion 252 is disposed in the upper trench portion 242 (see FIG. 10B) of the corresponding one of the wall trenches 24 and on the lower portion 251.

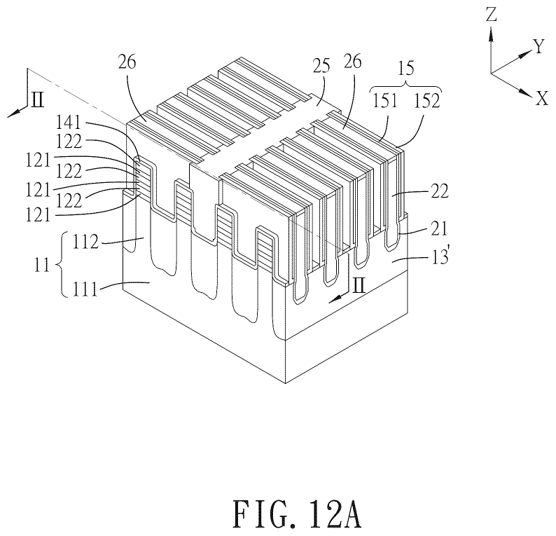

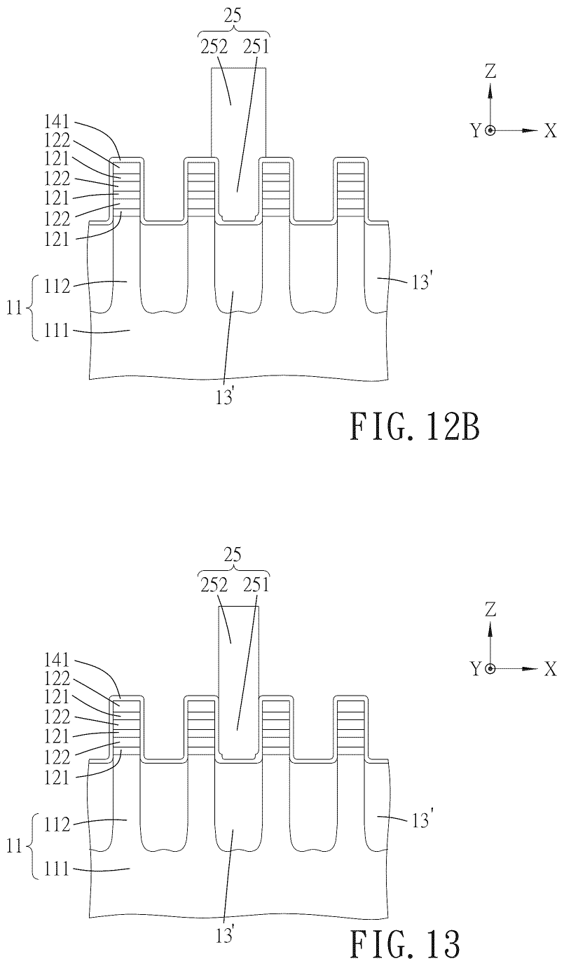

Referring to FIG. 1B and the example illustrated in FIGS. 12A and 12B, the method 100A then proceeds to step 111, where a plurality of nitride features 26 are formed, followed by removing remaining portions of the second mask layer 23 and the dummy gate electrodes 142. Step 111 may include sub-steps 1111 and 1112. FIG. 12B illustrates a cross-sectional view taken along line II-II of FIG. 12A.

In sub-step 1111, the ILD features 22 are partially etched to form a plurality of recesses (not shown), followed by respectively forming the nitride features 26 in the recesses. The ILD features 22 may be partially etched by a suitable etching process, for example, but not limited to, dry etching, wet etching, other suitable etching processes, or combinations thereof. The nitride features 26 may be formed by conformally depositing a nitride layer on the contact etch stop features 21, the etched ILD features 22 and other structures, followed by performing a planarization process (e.g., CMP or other suitable planarization processes) to remove an excess portion of the nitride layer, so as to obtain the nitride features 26. The nitride layer may be made of a nitride-based material. Other suitable materials for the nitride features 26 are within the contemplated scope of the present disclosure. The nitride features 26 are used to protect the etched ILD features 22 from being damaged in subsequent processes.

In sub-step 1112, the remaining portions of the second mask layer 23 and the dummy gate electrodes 142 are removed by a suitable etching process, for example, but not limited to, dry etching, wet etching, other suitable etching processes, or combinations thereof.

Referring to FIG. 1B and the example illustrated in FIG. 13, the method 100A then proceeds to step 112, where the upper portion 252 of each of the dielectric walls 25 is laterally recessed. Step 112 may be performed by a suitable etching process, such as dry etching. In this step, the material for the dielectric walls 25 has a high etching selectivity with respect to the dummy oxide layer 141 and the gate spacers 15. That is, for a suitable kind of etchant, the dielectric walls 25 can be readily etched, while the dummy oxide layer 141 and the gate spacers 15 are left slightly etched or substantially unetched.

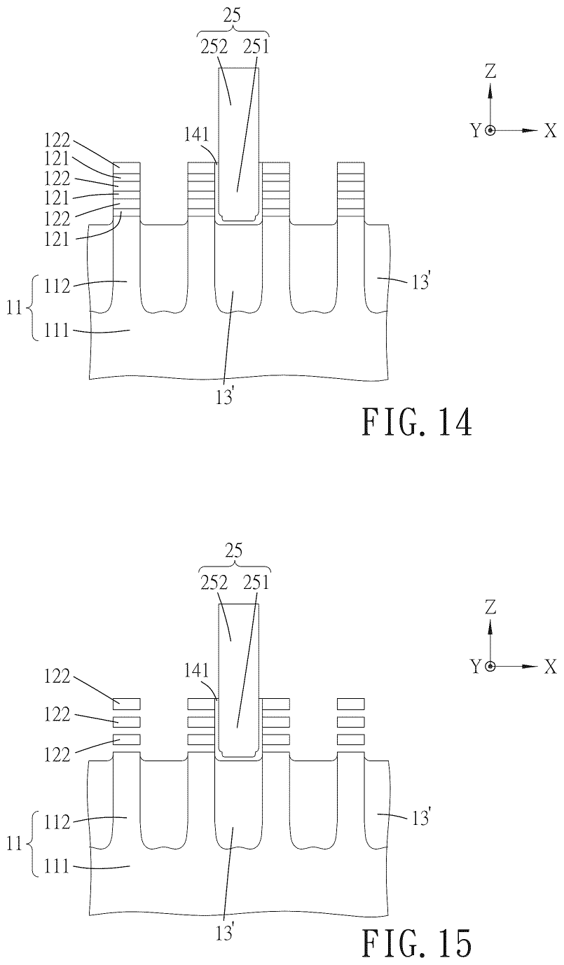

Referring to FIG. 1B and the example illustrated in FIG. 14, the method 100A then proceeds to step 113, where the dummy oxide layer 141 is partially removed. Step 113 may be performed by a suitable etching process, such as dry etching. After this step, a remaining portion of the dummy oxide layer 141 surrounds the lower portion 251 of each of the dielectric walls 25. In some embodiments, in this step, the isolation layer portions 13′ are substantially unetched.

Referring to FIG. 1B and the example illustrated in FIG. 15, the method 100A then proceeds to step 114, where the sacrificial features 121 are removed. Step 114 may be performed by a suitable etching process, for example, but not limited to, dry etching, wet etching, other suitable etching processes, or combinations thereof. Step 114 may be referred to as a sheet formation process (the channel features 122 resemble sheets).

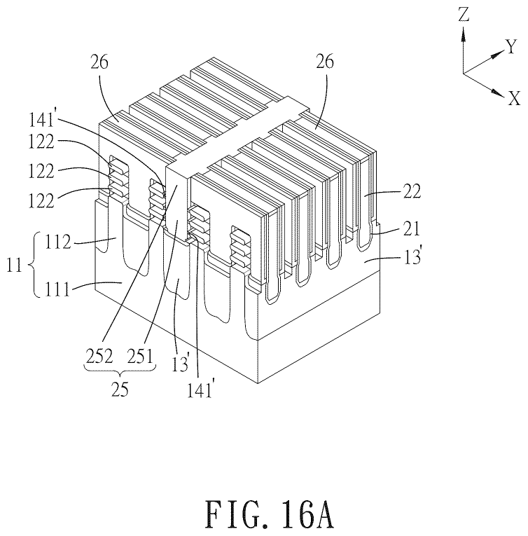

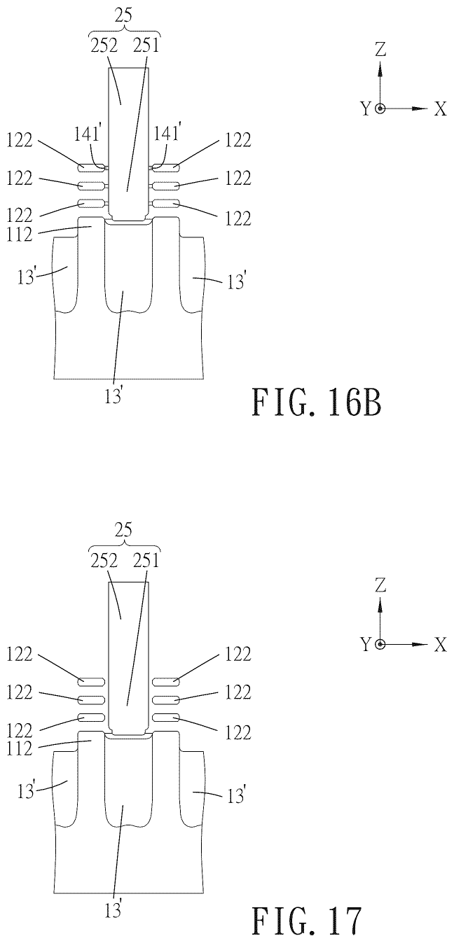

Referring to FIG. 1B and the example illustrated in FIGS. 16A and 16B, the method 100A then proceeds to step 115, where the remaining portion of the dummy oxide layer 141 is partially removed to form a plurality of liners 141′. FIG. 16B is a partially enlarged view of FIG. 16A. Each of the liners 141′ is disposed between a corresponding one of the channel features 122 and the lower portion 251 of a corresponding one of the dielectric walls 25. Step 115 may be performed by a suitable etching process, for example, but not limited to, dry etching, wet etching, other suitable etching processes, or combinations thereof.

In some embodiments, as shown in FIG. 17, the remaining portion of the dummy oxide layer 141 of the structure shown in FIG. 15 may be fully removed in step 115.

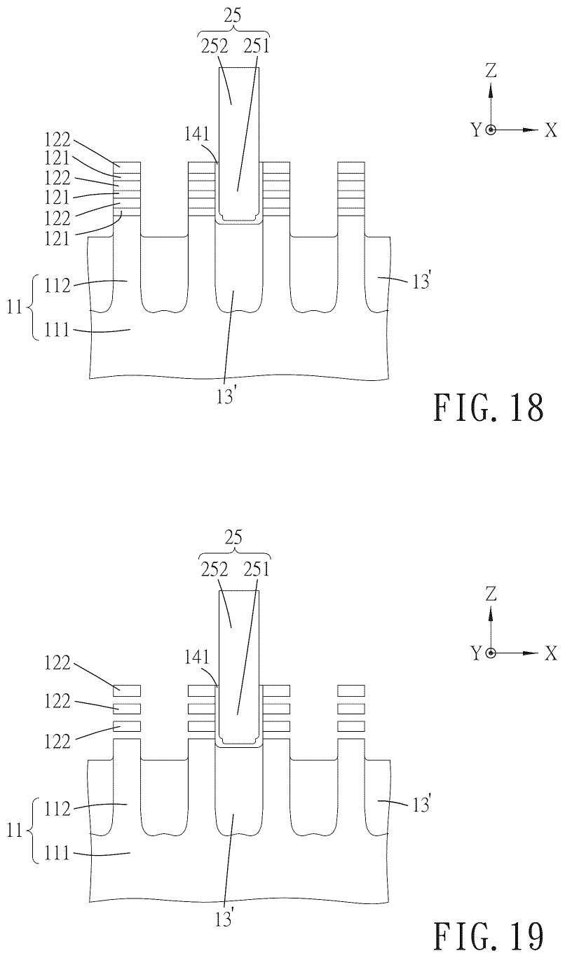

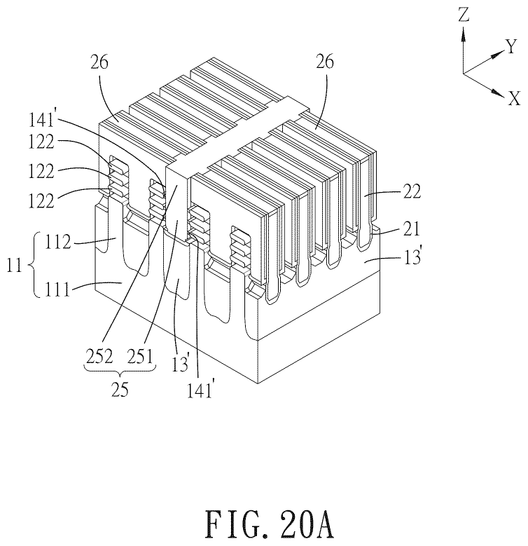

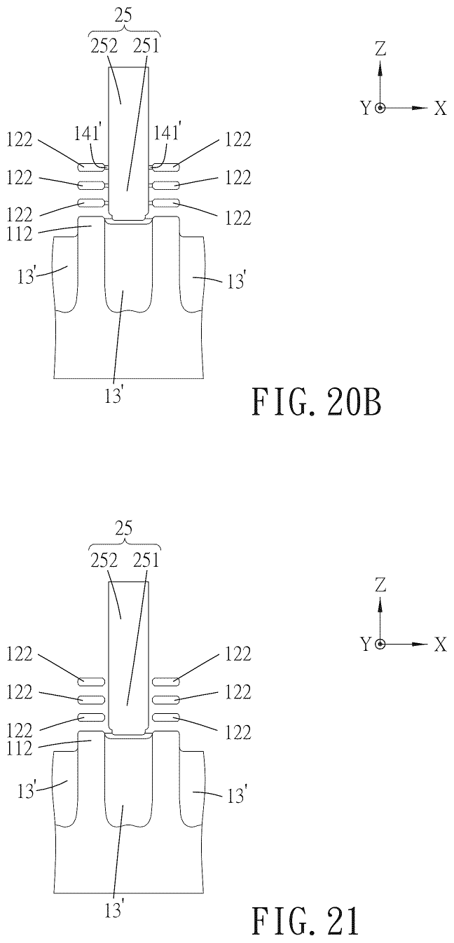

In some embodiments, as shown in FIG. 18, step 112 may be omitted, and in step 113, an etching process (e.g., dry etching) may be performed to partially remove the upper portion 252 of each of the dielectric walls 25 of the structure shown in FIG. 12B and the dummy oxide layer 141. In this case, the isolation layer portions 13′ may be partially etched. Afterwards, steps 114 and 115 are sequentially performed (see FIGS. 19 to 20B).

In some embodiments, as shown in FIG. 21, the remaining portion of the dummy oxide layer 141 of the structure shown in FIG. 19 may be fully removed.

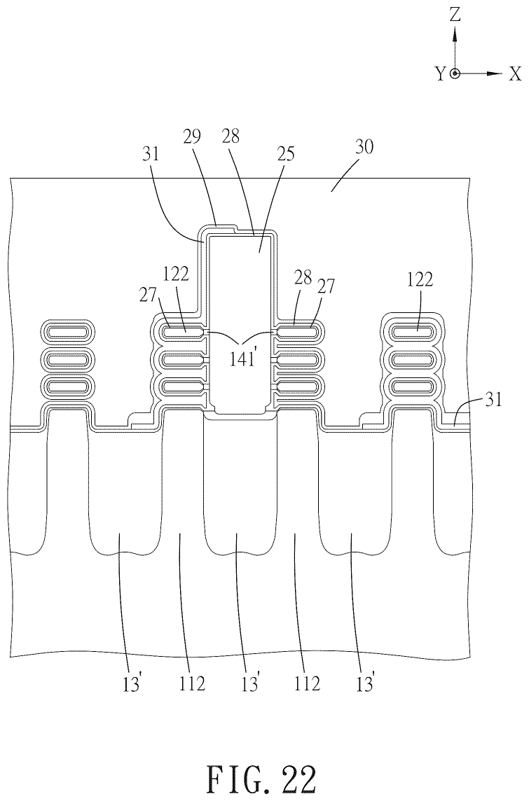

Referring to FIG. 1B and the example illustrated in FIG. 22, the method 100A then proceeds to step 116, where a plurality of interfacial layers 27, a high-k material layer 28, a first metal layer 29, and a second metal layer 30 are sequentially formed on the structure shown in FIG. 21. Step 116 may include sub-steps 1161 and 1162.

In sub-step 1161, the interfacial layers 27 may be formed by conducting a pre-clean process on the structure shown in FIGS. 20A or 20B to oxidize the channel features 122, so as to form the interfacial layers 27 which cover the channel features 122 and top surfaces of the fin portions 112 of the semiconductor substrate 11, and the isolation layer portions 13′, respectively. In some embodiments, the pre-clean process for forming the interfacial layers 27 may be conducted by one of RCA SC-1 (including ammonia, hydrogen peroxide and deionized water), RCA SC-2 (including hydrochloric acid, hydrogen peroxide and deionized water) and a combination thereof. Other suitable processes for forming the interfacial layers 27 are within the contemplated scope of the present disclosure. The interfacial layers 27 may include silicon oxide. Other suitable materials for the interfacial layers 27 are within the contemplated scope of the present disclosure.

In sub-step 1162, the high-k material layer 28, the first metal layer 29, and the second metal layer 30 are sequentially formed on the interfacial layers 27 and other portions of the structure shown in FIG. 20A that is not covered by the interfacial layers 27 by a suitable deposition process, for example, but not limited to, CVD, ALD, or other suitable deposition processes. The high-k material layer 28 may include hafnium oxide, silicon nitride, silicon oxynitride, titanium oxide, hafnium zirconium oxide, tantalum oxide, hafnium silicon oxide, zirconium oxide, zirconium silicon oxide, lanthanum oxide, aluminum oxide, yttrium oxide, strontium titanate, barium titanate, barium zirconate, lanthanum silicon oxide, aluminum silicon oxide, hafnium lanthanum oxide, hafnium silicon oxide, aluminum silicon oxide, hafnium tantalum oxide, hafnium titanium oxide, other suitable high-k materials, or combinations thereof. The first metal layer 29 and the second metal layer 30 may be made of a work-function metallic material and may have different conductivity types. For example, one of the first metal layer 29 and the second metal layer 30 may be made of an n-type metal or an n-type metal compound, and the other one of the first metal layer 29 and the second metal layer 30 may be made of a p-type metal or a p-type metal compound. In some embodiments, the n-type metal may include, for example, but not limited to, titanium (Ti), aluminum (Al), silver (Ag), manganese (Mn) and zirconium (Zr), or other suitable n-type metals. In some embodiments, the n-type metal compound may include, for example, but not limited to, tantalum carbide (TaC), tantalum carbide nitride (TaCN), tantalum silicon nitride (TaSiN), titanium silicon nitride (TiSiN), other suitable n-type metal compounds, or combinations thereof. In some embodiments, the p-type metal may include, for example, but not limited to, ruthenium (Ru), molybdenum (Mo), tungsten (W), platinum (Pt), or other suitable p-type metals. In some embodiments, the p-type metal compound may include, for example, but not limited to, titanium nitride (TiN), tantalum nitride (TaN), tungsten nitride (WN), zirconium disilicide (ZrSi₂), molybdenum disilicide (MoSi₂), tantalum disilicide (TaSi₂), nickel disilicide (NiSi₂₎, other p-type metal compounds, or combinations thereof. Other suitable materials for the first metal layer 29 and the second metal layer 30 are within the contemplated scope of the present disclosure. In some embodiments, a plurality of third metal layers 31 may be independently formed between the high-k material layer 28 and the first metal layer 29. The material for the third metal layers 31 may be the same as or similar to that for the first metal layer 29 or the second metal layer 30, and thus details thereof are omitted for the sake of brevity.

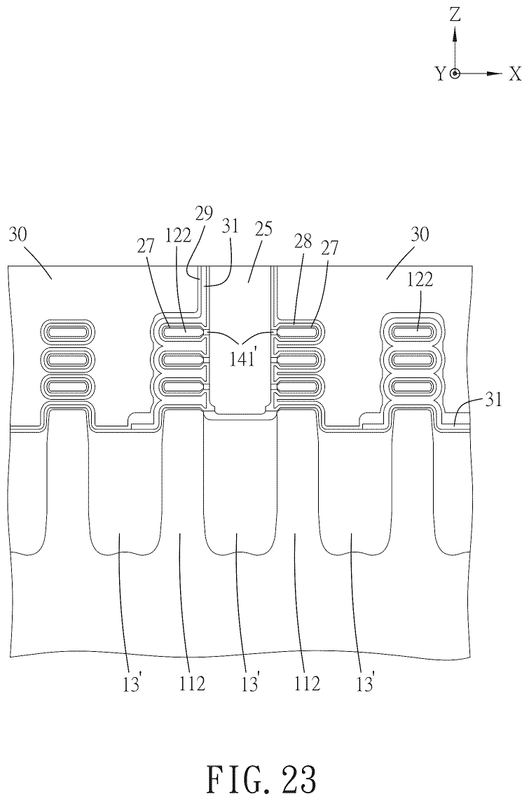

Referring to FIG. 1B and the example illustrated in FIG. 23, the method 100A then proceeds to step 117, where a planarization process (e.g., CMP or other suitable planarization processes) is performed to partially remove the second metal layer 30, the first metal layer 29, the third metal layer 31, the high-k material layer 28, and the dielectric walls 25.

Referring to FIG. 1B and the example illustrated in FIG. 24, the method 100A then proceeds to step 118, where a plurality of isolation features 32 are formed. Step 118 may include sub-step (i) conducting a photolithography process to pattern the structure shown in FIG. 23 so as to form a plurality of trenches (not shown), sub-step (ii) forming an isolation material layer (not shown) for the isolation features 32 on a top surface of the patterned structure and in the trenches, and sub-step (iii) conducting a planarization process (e.g., CMP or other suitable planarization processes) to remove an excess portion of the isolation material layer for the isolation features 32 on the top surface of the patterned structure, so as to obtain the isolation features 32. In some embodiments, in sub-step (i), each of the trenches may penetrate through the second metal layer 30 and the first metal layer 29, and may extend into a corresponding one of the isolation layer portions 13′, so as to form the second metal layer 30 into a plurality of second metal portions 30′ and to form the first metal layer 29 into a plurality of first metal portions 29′. In some embodiments, in sub-step (iii), the second metal portions 30′, the first metal portions 29′, the high-k material layer 28, and the dielectric walls 25 may be partially removed. The isolation material layer for the isolation features 32 may include, for example, but not limited to, oxide, silicon nitride, silicon carbon nitride, silicon oxycarbonnitride, or other low-k materials. Other suitable materials for the isolation features 32 are within the contemplated scope of the present disclosure. In some embodiments, each of the dielectric walls 25 may be disposed between two adjacent ones of the isolation features 32. After step 118, the semiconductor structure 200A is therefore obtained. In some embodiments, the semiconductor structure 200A may be divided into a plurality of the semiconductor structures 41, 42, 43, 44 that are spaced apart from each other in the X direction. In some embodiments, the semiconductor structures 41, 43 may be n-type metal-oxide-semiconductor field-effect transistors (NMOSFETs) and the semiconductor structures 42, 44 may be p-type metal-oxide-semiconductor field-effect transistor (PMOSFETs), and vice versa.

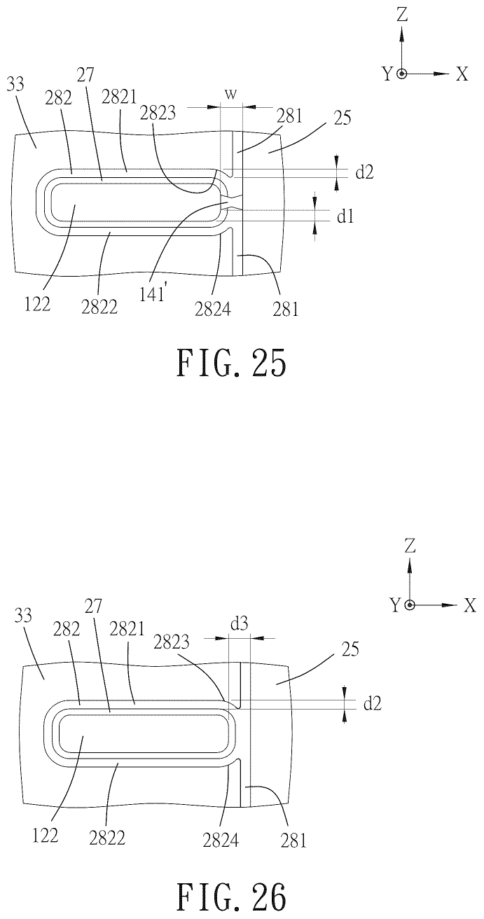

In some embodiments, as shown in FIG. 25 (i.e., a partially enlarged schematic view of FIG. 24), electrical characteristics (e.g., gate-to-drain capacitance (Cgd), gate control capability, and the like) of the semiconductor structures 41, 42, 43, 44 may depend on a width (w) of the liners 141′, a first distance (d1), and a second distance (d2). In some embodiments, the width (w) of the liner 141′ may range from about 0 nm to about 6 nm. When the width (w) of the liner 141′ is greater than about 6 nm, Cgd of the semiconductor structures 41, 42, 43, 44 may increase, which may cause a degradation of electrical performance thereof. The first distance (d1) is defined as a distance between a lower surface of each of the liners 141′ and a lower surface of a corresponding one of the channel features 122. In some embodiments, the first distance (d1) may range from about 0 nm to about 3 nm. When the first distance (d1) increases, the semiconductor structures 41, 42, 43, 44 may exhibit an improved gate control capability, which is conducive to mitigating a short channel effect. In some embodiments, the high-k material layer 28 may include a plurality of first portions 281 and a plurality of second portions 282. The first portions 281 are disposed on a side surface of a corresponding one of the dielectric walls 25. Each of the second portions 282 may have an upper surface 2821, a lower surface 2822 opposite to the upper surface 2821 in the Z direction, an upper corner surface 2823 connected between the upper surface 2821 and a corresponding one of the first portions 281, and a lower corner surface 2824 connected between the lower surface 2822 and a corresponding one of the first portions 281. The upper corner surface 2823 and the lower corner surface 2824 are proximate to the corresponding one of the dielectric walls 25. The upper corner surface 2823 (or the lower corner surface 2824) has a corner end at which the upper corner surface 2823 (or the lower corner surface 2824) is connected to the corresponding one of the first portions 281. The second distance (d2) is defined as a distance between a projection of the upper surface 2821 (or the lower surface 2822) on the corresponding one of the dielectric walls 25 and a projection of the corner end of the upper corner surface 2823 (or the lower corner surface 2824) on the corresponding one of the dielectric walls 25. In some embodiments, the second distance (d2) may range from about 0 nm to about 3 nm. When the second distance (d2) is greater than about 3 nm, capacitance of the semiconductor structures 41, 42, 43, 44 (see FIG. 24) may increase, resulting in a degradation (e.g., an increased RC time delay) of the electrical performance thereof. It is noted that the third metal layer 31 and corresponding ones of the first metal portions 29′ and the second metal portions 30′ (shown in FIG. 24) may be collectively referred to as a metal gate portion 33.

In some embodiments, as shown in FIG. 26 (similar to FIG. 25), the semiconductor device 200A may not include the liners 141′, so that each of the interfacial layers 27 may fully cover a corresponding one of the channel features 122, each of the second portions 282 covers a corresponding one of the interfacial layers 27, and the first portions 281 are formed as a continuous layer that covers the side surface of the corresponding one of the dielectric walls 25 and that is connected to the second portions 282. In this case, compared to the structure shown in FIG. 25, the gate control capability of the semiconductor structures 41, 42, 43, 44 may be improved while the capacitance thereof may be increased. In addition, the gate control capability and the short channel effect of the semiconductor structures 41, 42, 43, 44 may depend on a third distance (d3), which is defined as a distance between a side surface of each of the channel features 122 that is proximate to the corresponding one of the dielectric walls 25 and the corresponding one of the dielectric walls 25. In some embodiments, the third distance (d3) may range from about 2 nm to about 5 nm. When the third distance (d3) is less than about 2 nm or greater than about 5 nm, the short channel effect and the degradation of the electrical performance of the semiconductor structures 41, 42, 43, 44 may be increased.

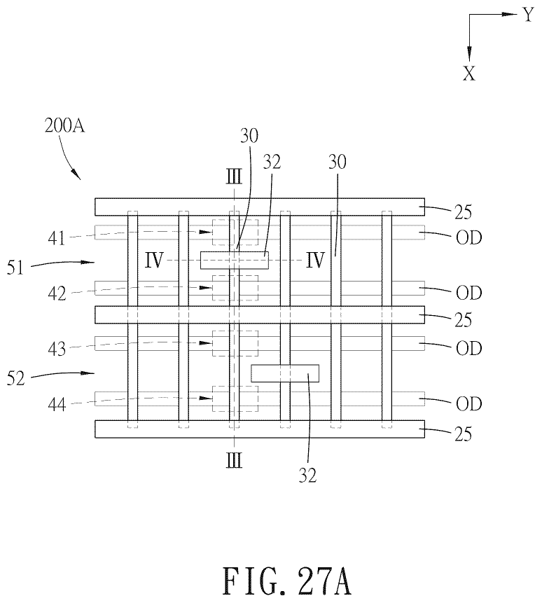

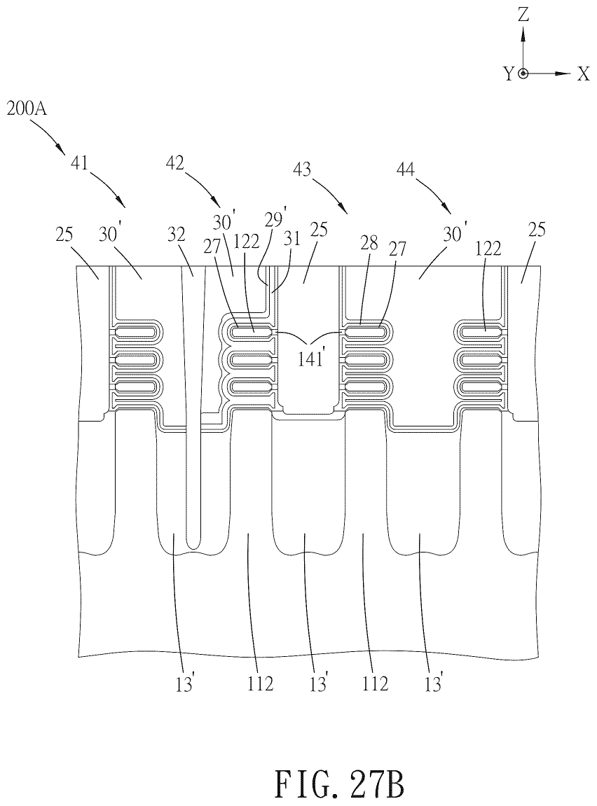

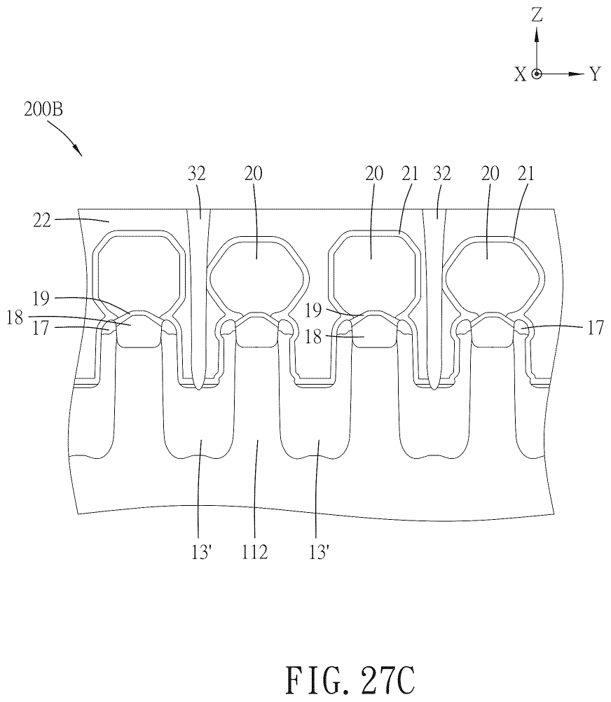

In some embodiments, as shown in FIGS. 27A to 27C, the semiconductor device 200A may include a plurality of semiconductor cells 51, 52 (e.g., semiconductor memory cells) that are separated from each other by a corresponding one of the dielectric walls 25 along the X direction and a plurality of oxide-definition (OD) regions, at which the semiconductor structures 41, 42, 43, 44 are formed. FIG. 27B illustrates a cross-sectional view taken along line III-III of FIG. 27A. FIG. 27C illustrates a cross-sectional view taken along line IV-IV of FIG. 27A. In this case, each of the dielectric walls 25 may serve as a cell boundary. The semiconductor cell 51 may include a plurality of the semiconductor structures (e.g., the semiconductor structures 41, 42), and the semiconductor cell 52 may include a plurality of the semiconductor structures (e.g., the semiconductor structures 43, 44). As shown in FIG. 27C, the dielectric walls 25 is not found among the source/drain features 20.

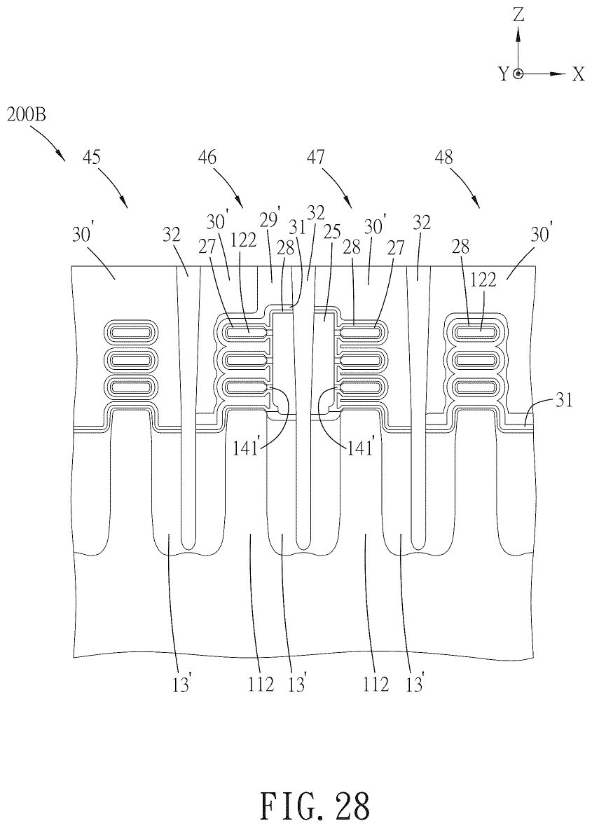

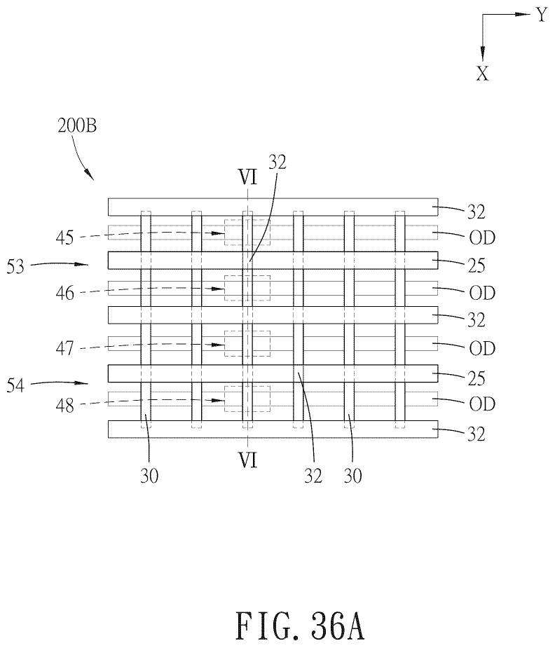

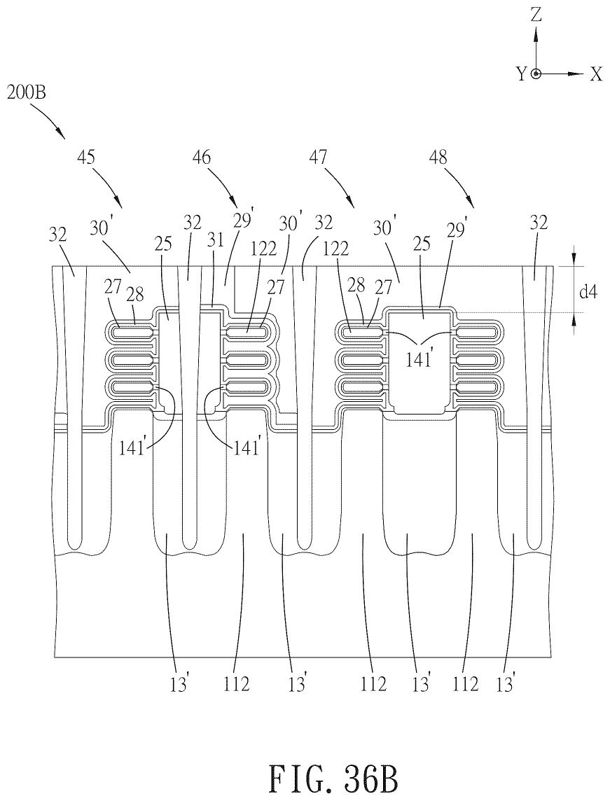

FIGS. 28 and 36A illustrate a schematic view of a semiconductor device 200B in accordance with some embodiments. The semiconductor device 200B is similar to the semiconductor device 200A except that, in the semiconductor device 200B, each of the dielectric walls 25 is formed between two corresponding cell boundaries, has a reduced height, and is penetrated by a corresponding one of the isolation features 32.

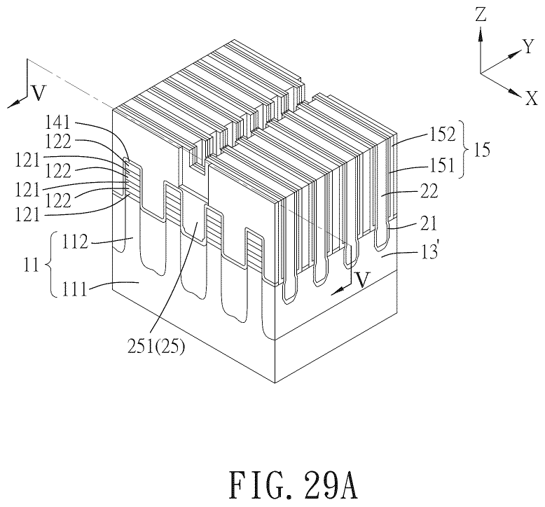

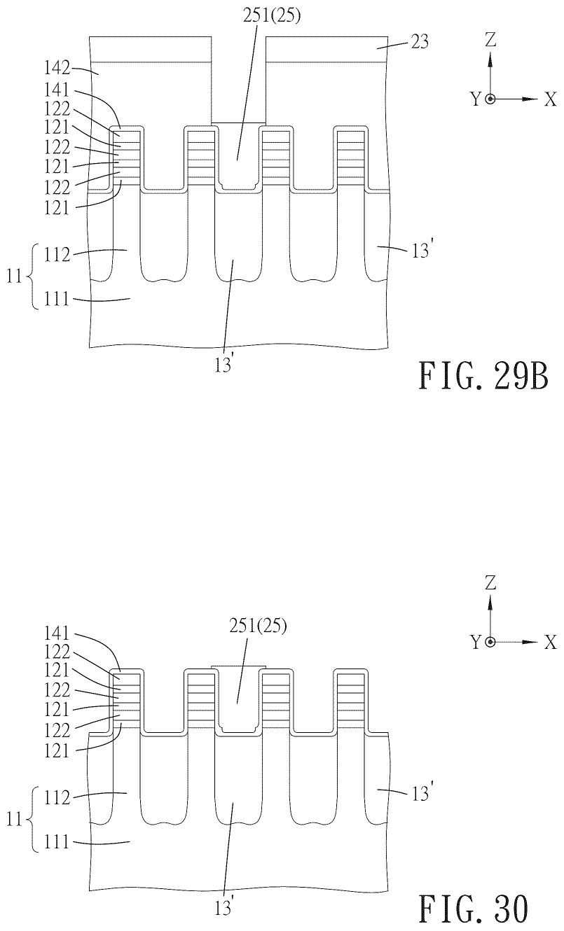

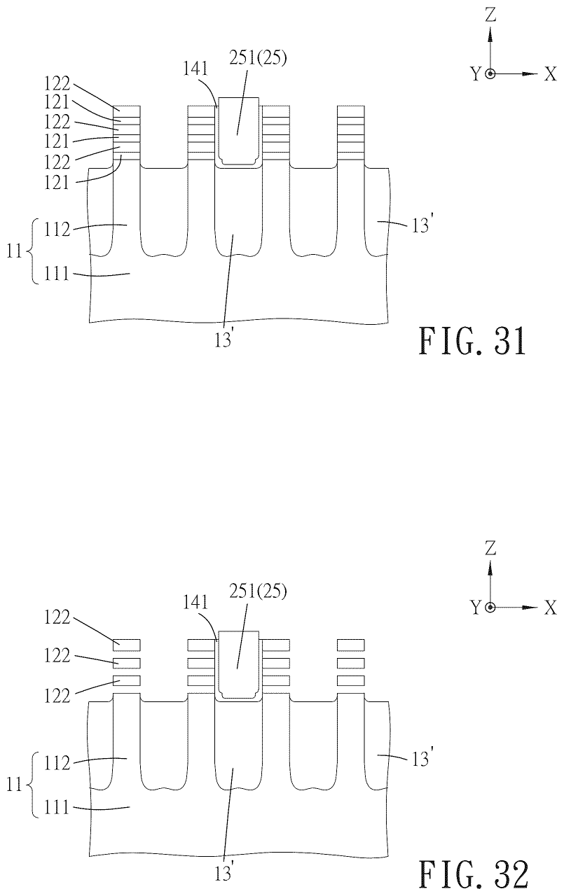

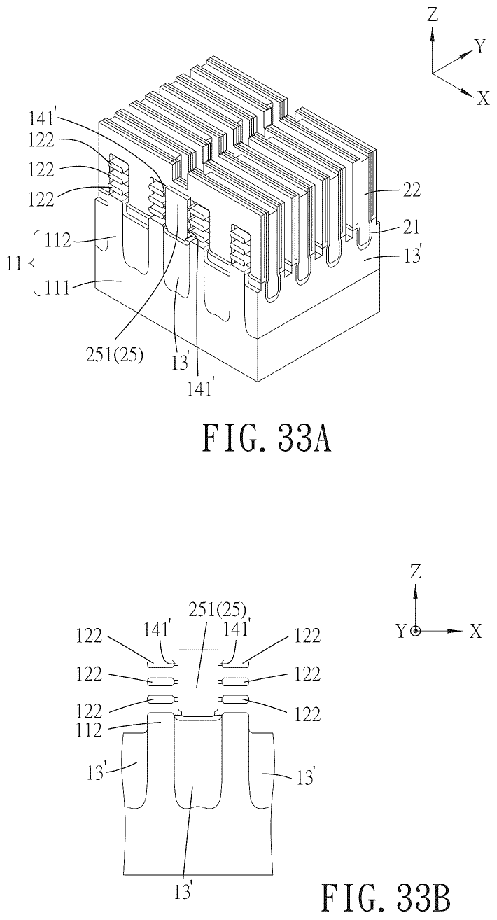

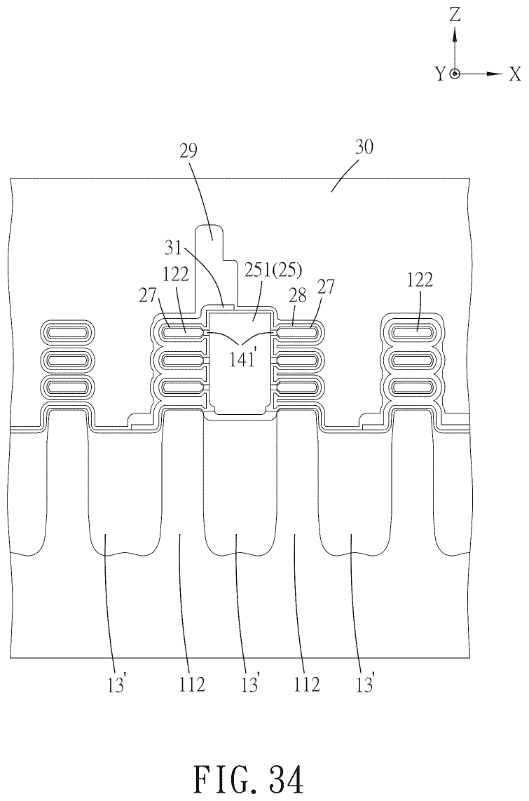

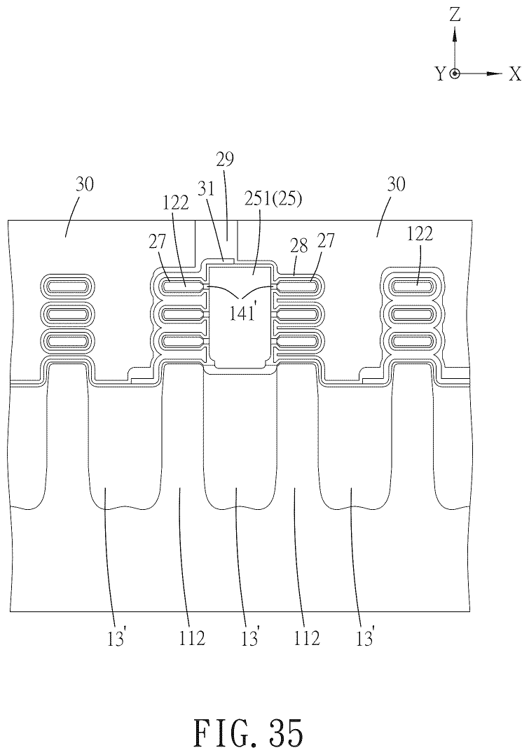

Referring to FIGS. 29A to 35, the semiconductor device 200B may be made using a method 100B similar to the method 100A except that, the dielectric walls 25 are etched back after step 110 and before step 111 (see FIGS. 29A and 29B), the nitride features 26 are not formed in step 111 (see FIG. 34A), and each of the dielectric walls 25 is penetrated by the corresponding one of the isolation features 31 in step 118, so as to obtain the semiconductor device 200B shown in FIG. 28.

As shown in FIGS. 29A and 29B, the upper portions 252 (see FIG. 11) of the dielectric walls 25 are etched away by a suitable etching process (e.g., dry etching), and the lower portions 251 of the dielectric walls 25 remain. FIG. 29B is a cross-sectional view taken along line V-V of FIG. 29A. After removal of the upper portions 252 of the dielectric walls 25, steps 111 to 118 are sequentially performed.

In some embodiments, as shown in FIGS. 36A and 36B, the semiconductor device 200B may include a plurality of semiconductor cells 53, 54 (e.g., semiconductor memory cells) that are separated from each other by one of the isolation features 32 along the X direction. FIG. 36B illustrates a cross-sectional view taken along line VI-VI of FIG. 36A. In this case, each of the isolation features 32 may serve as a cell boundary. In some embodiments, the semiconductor cell 53 may include a plurality of semiconductor structures (e.g., the semiconductor structures 45, 46), and the semiconductor cell 54 may include a plurality of semiconductor structures (e.g., the semiconductor structures 47, 48). In some embodiments, each of the semiconductor structures 45, 46, 47, 48 may be an NMOSFET or a PMOSFET. In some embodiments, an upper surface of each of the dielectric walls 25 is lower than an upper surface of the second metal portion 30′ by a fourth distance (d4) ranging from about 5 nm to about 15 nm.

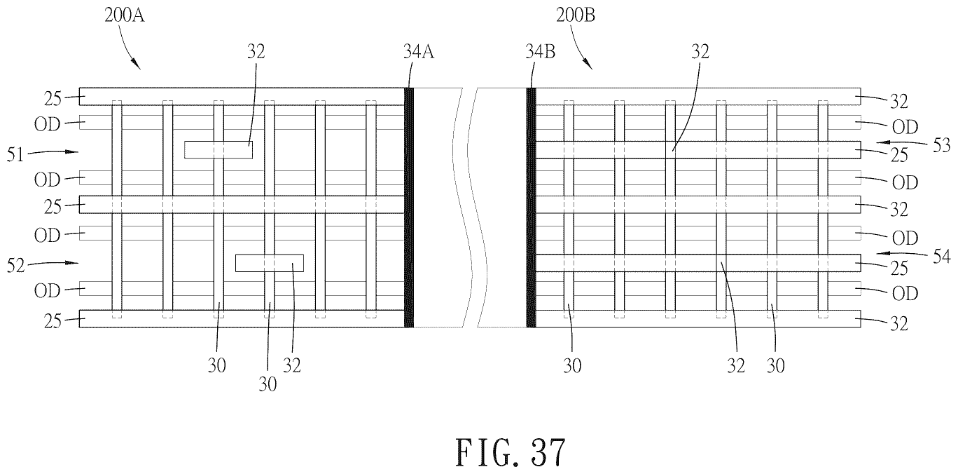

In some embodiments, as shown in FIG. 37, the semiconductor devices 200A, 200B may be simultaneously formed in an integrated circuit (IC) chip (not shown) by mask patterning. In this case, the semiconductor devices 200A, 200B may be respectively connected to two dummy gates 34A, 34B, and the dummy gates 34A, 34B are located between the semiconductor devices 200A, 200B. In some embodiments, other semiconductor structures (not shown) may exist between the dummy gates 34A, 34B.

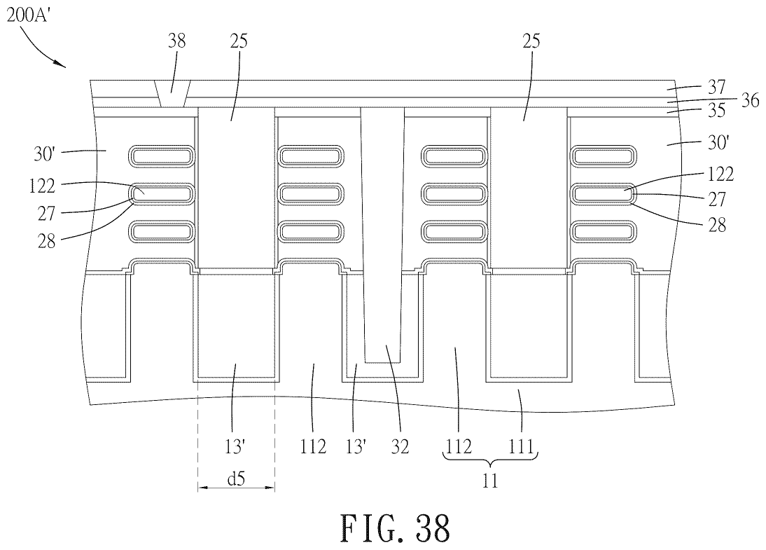

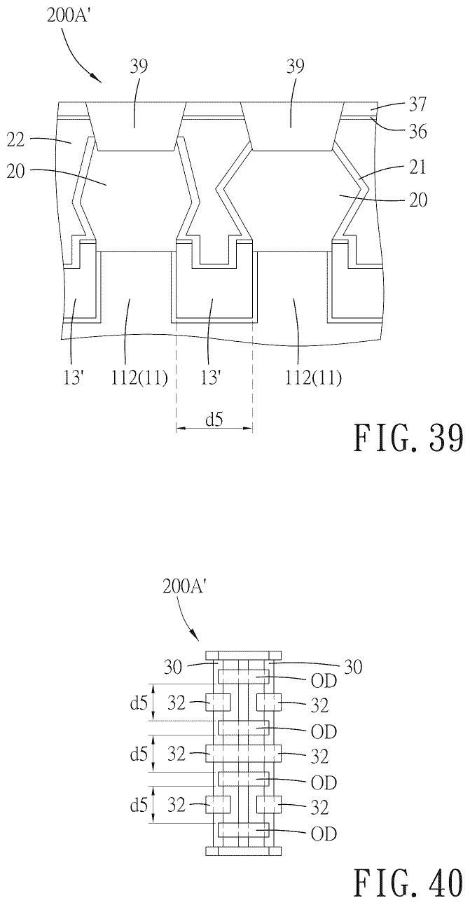

FIGS. 38 to 40 illustrate a semiconductor device 200A′ in accordance with some embodiments. FIG. 40 illustrates a layout of the semiconductor device 200A′. The semiconductor device 200A′ is generally similar to the semiconductor device 200A, except that, the semiconductor device 200A′ further includes a plurality of metal portions 35, an etch stop layer 36, a dielectric layer 37, a via contact 38, and a plurality of conductive features 39. As shown in FIG. 38, the metal portions 35 are disposed on the second metal layer portions 30′, respectively. The metal portions 35 may be made of fluorine-free tungsten (FFW). Other suitable materials for the metal portions 35 are within the contemplated scope of the present disclosure. The etch stop layer 36 is disposed on the metal portions 35, the dielectric walls 25, and the isolation features 32. The material for the etch stop layer 36 may be the same as or similar to that for the contact etch stop feature 21 as described in step 108, and thus details thereof are omitted for the sake of brevity. The dielectric layer 37 is disposed on the etch stop layer 36 opposite to the semiconductor substrate 11. The material for the dielectric layer 35 may be the same as or similar to that of the dielectric layer for forming the isolation features 31 as described in step 118, and thus details thereof are omitted for the sake of brevity. The via contact 38 is disposed in the dielectric layer 37 and the etch stop layer 36, and is in contact with a corresponding one of the metal portions 35. As shown in FIG. 39, the etch stop layer 36 and the dielectric layer 37 are sequentially disposed on the ILD feature 22, and the conductive features 39 penetrate through the dielectric layer 37, the etch stop layer 36, a portion of the ILD feature 22, the contact etch stop feature 21, and extend into the source/drain features 20, respectively.

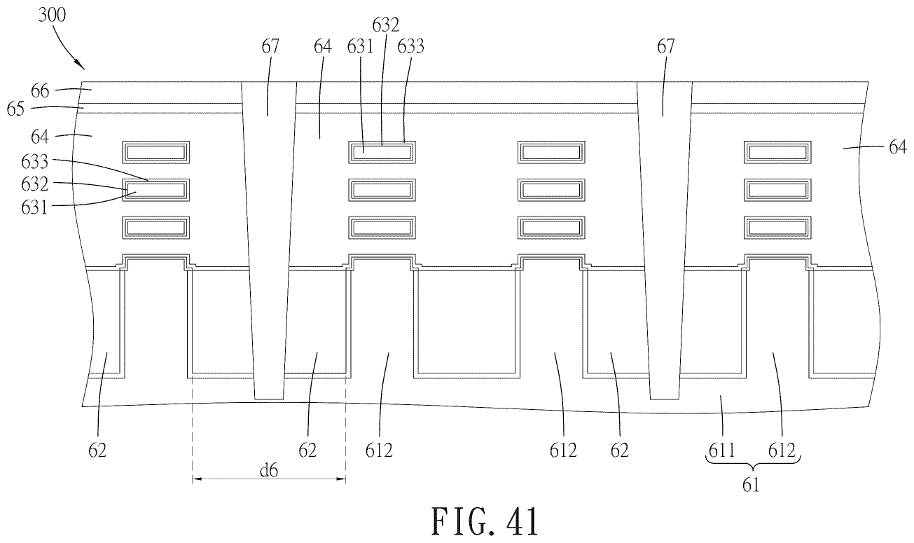

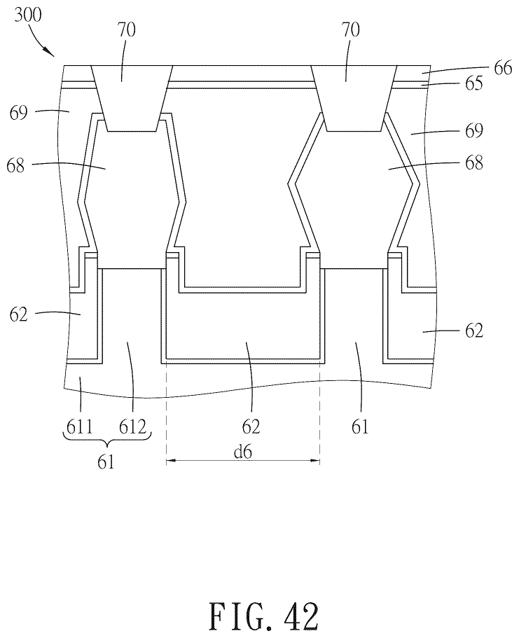

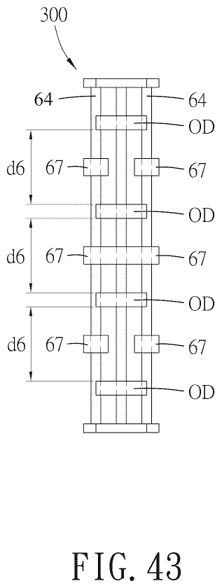

FIGS. 41 to 43 illustrate a semiconductor device 300. FIG. 43 illustrates a layout of the semiconductor device 300. The semiconductor device 300 is generally similar to the semiconductor device 200A′, except that, the semiconductor device 300 does not include any dielectric wall. As shown in FIG. 41, the semiconductor device 300 includes a semiconductor substrate 61, a plurality of isolation layer portions 62, a plurality of channel features 631, a plurality of interfacial layer 632, a plurality of high-k material layers 633, a plurality of metal portions 64, an etch stop layer 65, a dielectric layer 66, a plurality of isolation features 67, a plurality of source/drain features 68, an interlayer dielectric feature 69, and a plurality of conductive features 70. The materials and techniques for forming the elements 61 to 67 are similar to those for the elements 11, 13′, 122, 27, 28, 30′, 36, 37, 32, 20, 22, 39 as described above, and thus details thereof are omitted for the sake of brevity.

In some embodiments, a ratio of a distance (d5) defined between two adjacent ones of the oxide-definition (OD) regions (i.e., the fin portions 112 of the semiconductor substrate 11) of the semiconductor device 200A′ to a distance (d6) defined between two adjacent ones of fin portions 612 of the semiconductor substrate 61 of the semiconductor structure 300 may range from about 0.65 to about 0.75. In other words, a functional density (i.e., the number of the semiconductor structures) of the semiconductor device 200A′ is higher than that of the semiconductor device 300. In some embodiments, the distance (d5) may range from about 25 nm to about 46 nm, and other range values are also within the contemplated scope of the disclosure. The distance (d6) may range from about 40 nm to about 80 nm. In some embodiments, as shown in FIG. 38, an upper surface of each of the dielectric walls 25 may have a width not greater than the distance (d5). In some embodiments, a difference value between the width and the distance (d5) may range from about 0 nm to about 20 nm. In some embodiments, a capacitance of the semiconductor structures in the semiconductor device 200A′ may be less than that of the semiconductor structures in the semiconductor device 300 by from about 10% to about 15%, and accordingly, a power efficiency of the semiconductor structures in the semiconductor device 200A′ may be greater than that of the semiconductor structures in the semiconductor device 300 by from about 10% to about 15%.

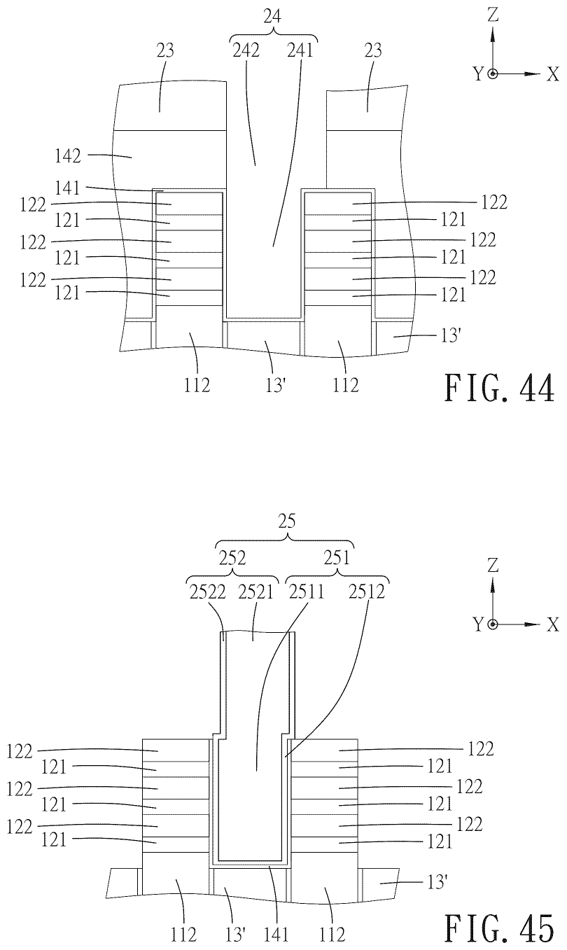

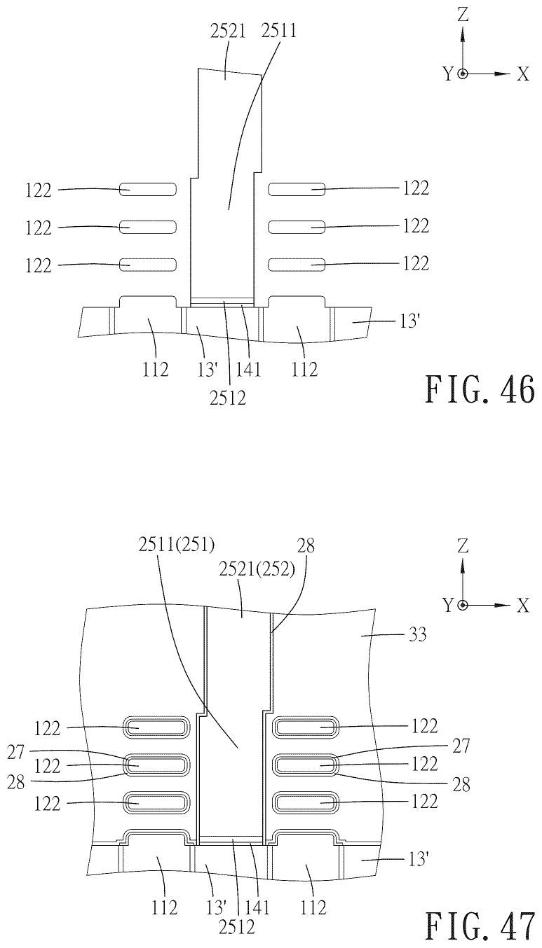

In some embodiments, as shown in FIGS. 44 to 47, the upper portion 252 of each of the dielectric walls 25 may not be in alignment with the lower portion 251 of each of the dielectric walls 25 in the Z direction. As shown in FIG. 44, in step 109, the second mask layer 23 and the dummy gate electrodes 142 may be over-etched due to process variations (e.g., an overlay shift in the photolithography process). Afterwards, steps 110 to 118 of the method 100A are sequentially performed. In this case, as shown in FIG. 45, each of the dielectric walls 25 is formed as a two-layered structure, where the lower portion 251 of each of the dielectric walls 25 includes a main region 2511 and an outer region 2512, and the upper portion 252 of each of the dielectric walls 25 includes a main region 2521 and an outer region 2522. As shown in FIG. 46, in step 115 of the method 100A, the dummy oxide layer 141 and the dielectric walls 25 are partially removed (e.g., by a suitable etching process), and the main regions 2511, 2521 and residuals of the dummy oxide layer 141 and the outer region 2512 remain. The main region 2521 is not in alignment with the main region 2511.

In this disclosure, by forming at least one dielectric wall and at least one isolation feature in a semiconductor device, the semiconductor device may have an increased density of functional semiconductor structures (e.g., transistors), and each of the functional semiconductor structures may have a reduced capacitance and an improved power performance. The at least one dielectric wall and the at least one isolation feature may be spaced apart from each other in the semiconductor device, or the at least one isolation feature may penetrate through the at least one dielectric wall. In addition, the at least one dielectric wall is formed before the formation of the metal gate structure. Therefore, the size of the metal gate endcap portions can be reduced without affecting the threshold voltage (Vₜₕ) of the semiconductor device.

In accordance with some embodiments of the present disclosure, a semiconductor device includes: a semiconductor substrate, a first semiconductor structure, a second semiconductor structure, a third semiconductor structure, a dielectric wall, and a first isolation feature. The first semiconductor structure, the second semiconductor structure and the third semiconductor structure are disposed on the semiconductor substrate. The first semiconductor structure is disposed between the second semiconductor structure and the third semiconductor structure. The dielectric wall is disposed on the semiconductor substrate and is connected between the first semiconductor structure and the second semiconductor structure. The first isolation feature is disposed between the first semiconductor structure and the third semiconductor structure, and extends into the semiconductor substrate.

In accordance with some embodiments of the present disclosure, the semiconductor substrate includes a plurality of fin portions and a plurality of isolation portions which alternate with one another in an X direction. The dielectric wall is disposed on a corresponding one of the isolation portions in a Z direction transverse to the X direction. The first semiconductor structure and the second semiconductor structure are respectively disposed on two adjacent ones of the fin portions that are located at two opposite sides of the corresponding one of the isolation portions.

In accordance with some embodiments of the present disclosure, the semiconductor device further includes a second isolation feature that penetrates through the dielectric wall and that extends into the corresponding one of the isolation portions.

In accordance with some embodiments of the present disclosure, each of the first semiconductor structure, the second semiconductor structure and the third semiconductor structure includes a metal portion, and an upper surface of the dielectric wall is lower than an upper surface of the metal portion by a distance ranging from 5 nm to 15 nm.

In accordance with some embodiments of the present disclosure, each of the first semiconductor structure and the second semiconductor structure includes a channel feature and a liner. The channel feature is connected to the dielectric wall through the liner.

In accordance with some embodiments of the present disclosure, the liner has a width in the X direction, and the width ranges from 0 nm to 6 nm.

In accordance with some embodiments of the present disclosure, a lower surface of the liner and a lower surface of the channel feature are separated from each other by a distance in the Z direction. The distance ranges from 0 nm to 3 nm.

In accordance with some embodiments of the present disclosure, a semiconductor device includes a semiconductor substrate, a first semiconductor structure, a second semiconductor structure, a third semiconductor structure, a dielectric wall, and a first isolation feature. The semiconductor substrate includes a first fin portion, a second fin portion, a third fin portion, a first isolation portion, and a second isolation portion. The first isolation portion is disposed between the first fin portion and the second fin portion. The second isolation portion is disposed between the first fin portion and the third fin portion. The first semiconductor structure, the second semiconductor structure, and the third semiconductor structure are disposed on the first fin portion, the second fin portion and the third fin portion, respectively. The dielectric wall is disposed on the first isolation portion and is connected between the first semiconductor structure and the second semiconductor structure. The first isolation feature is disposed between the first semiconductor structure and the third semiconductor structure, and extends into the second isolation portion.

In accordance with some embodiments of the present disclosure, the semiconductor device further includes a second isolation feature that penetrates through the dielectric wall and that extends into the first isolation portion.

In accordance with some embodiments of the present disclosure, each of the first semiconductor structure, the second semiconductor structure, and the third semiconductor structure includes a metal portion. An upper surface of the dielectric wall is lower than an upper surface of the metal portion by a distance ranging from 5 nm to 15 nm.

In accordance with some embodiments of the present disclosure, each of the first semiconductor structure and the second semiconductor structure includes a channel feature and a liner. The liner is connected between the channel feature and the dielectric wall.

In accordance with some embodiments of the present disclosure, the liner has a width ranging from 0 nm to 6 nm.

In accordance with some embodiments of the present disclosure, the semiconductor device further includes a high dielectric constant material layer that includes a first portion and a second portion. The first portion is disposed on a side surface of the dielectric wall. The second portion partially covers the channel feature and has a surface and a corner surface that is connected between the surface and the first portion and that has a corner end at which the corner surface is connected to the first portion. A projection of the surface on the dielectric wall and a projection of the corner end of the corner surface on the dielectric wall are separated from each other by a distance ranging from 0 nm to 3 nm.

In accordance with some embodiments of the present disclosure, the semiconductor device further includes a high dielectric constant material layer that includes a first portion and a second portion. The first portion is disposed on a side surface of the dielectric wall. The second portion fully covers the channel feature and is connected to the first portion. A side surface of the channel feature that is proximate to the dielectric wall is separated from the dielectric wall by a distance ranging from 2 nm to 5 nm.

In accordance with some embodiments of the present disclosure, a method for manufacturing a semiconductor device includes: forming a first stack, a second stack and a third stack that are spaced apart from each other in a Y direction and that are disposed on a semiconductor substrate in a Z direction transverse to the Y direction, the first stack being located between the second stack and the third stack, each of the first stack, the second stack and the third stack including a plurality of sacrificial features and a plurality of channel features that are alternately stacked on the semiconductor substrate; forming a plurality of dummy poly gates on the first stack, the second stack and the third stack along the Z direction, respectively, each of the dummy poly gates including a dummy oxide layer and a dummy gate electrode; forming a mask layer on the dummy poly gates opposite to the semiconductor substrate along the Z direction; removing a portion of the mask layer and portions of the dummy poly gates, so as to form a wall trench between the first stack and the second stack; forming a dielectric wall in the wall trench, the dielectric wall being connected between the first stack and the second stack; removing the sacrificial features of each of the first stack, the second stack and the third stack; forming a metal layer over the semiconductor substrate and the channel features of each of the first stack, the second stack and the third stack; and forming a first isolation feature located between the channel features of the first stack and the channel features of the third stack.

In accordance with some embodiments of the present disclosure, the method further includes, after formation of the dielectric wall and before removal of the sacrificial features, removing remaining portions of the mask layer and remaining portions of the dummy gate electrodes and a portion of the dummy oxide layer, so that a lower portion of the dielectric wall is surrounded by a remaining portion of the dummy oxide layer.

In accordance with some embodiments of the present disclosure, the method further includes, after the removal of the sacrificial features and before formation of the metal layer, partially etching the remaining portion of the dummy oxide layer so as to form a plurality of liners, each of the liners being connected between a corresponding one of the channel features of the first stack and the second stack, and the dielectric wall.

In accordance with some embodiments of the present disclosure, the method further includes, after the removal of the sacrificial features and before formation of the metal layer, fully etching the remaining portion of the dummy oxide layer and forming a high dielectric constant material layer that covers the channel features of the first stack and the second stack, and the dielectric wall.

In accordance with some embodiments of the present disclosure, the method further includes, after formation of the dielectric wall and before removal of the sacrificial features, partially etching the dielectric wall, and removing remaining portions of the mask layer and the dummy poly gates.

In accordance with some embodiments of the present disclosure, in the formation of the first isolation feature, the method further includes forming a second isolation feature that penetrates through the dielectric wall.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first stack of nanosheet channel regions having a first gate engaging the first stack;
a second stack of nanosheet channel regions having a second gate engaging the second stack;
a third stack of nanosheet channel regions having a third gate engaging the third stack;
a dielectric wall disposed extending between the first gate and the second gate; and
a first isolation feature disposed between the second gate and the third gate; and wherein in a first cross-sectional view, a sidewall of the dielectric wall interfaces a gate dielectric of the first gate and the second gate, and wherein the first isolation feature interfaces a metal layer of the second gate and a metal layer of the third gate.

2. The semiconductor device as claimed in claim 1, wherein the dielectric wall includes a liner layer.

3. The semiconductor device as claimed in claim 1, wherein the gate dielectric layer of each of the first gate, second gate and third gate is at least one of an interfacial layer or a high-k dielectric layer.

4. The semiconductor device as claimed in claim 1, wherein a bottommost portion of the first isolation feature is below a bottommost portion of the dielectric wall.

5. The semiconductor device as claimed in claim 1, wherein the dielectric wall comprise a different material than the first isolation feature.

6. The semiconductor device as claimed in claim 1, further comprising:
a second isolation feature interfacing the first gate at a sidewall of the first gate opposing a sidewall of the first gate interfacing the dielectric wall in a cross-sectional view.

7. The semiconductor device as claimed in claim 1, wherein the first isolation feature extends between a first source/drain feature and a second source/drain feature in another cross-sectional view.

8. The semiconductor device as claimed in claim 1,
wherein the first stack of nanosheet channel regions have a high-k dielectric layer of the first gate surrounding each nanosheet channel region of the first stack of nanosheet channel regions;
wherein the second stack of nanosheet channel regions have a high-k dielectric layer of the second gate surrounding each nanosheet channel region of the second stack of nanosheet channel regions; and
wherein the third stack of nanosheet channel regions have a high-k dielectric layer of the third gate surrounding each nanosheet channel region of the third stack of nanosheet channel regions.

9. The semiconductor device as claimed in claim 1,
wherein the third stack of nanosheet channel regions have a high-k dielectric layer of the third gate surrounding each nanosheet channel region;
wherein the second stack of nanosheet channel regions have a high-k dielectric layer of the second gate extending on at least three sidewalls of each nanosheet channel region in a cross-sectional view, wherein the high-k dielectric layer of the second gate is omitted from a portion of a fourth sidewall of each nanosheet channel region, an oxide liner extending from the fourth sidewall to the dielectric wall; and
wherein the first stack of nanosheet channel regions have a high-k dielectric layer of the first gate extending on at least three sidewalls of each nanosheet channel region in the cross-sectional view, wherein the high-k dielectric layer of the first gate is omitted from a portion of a fourth sidewall of each nanosheet channel region, the oxide liner extending from the fourth sidewall to the dielectric wall.

10. A semiconductor device, comprising:
a first vertical stack of nanosheet channel regions, wherein the first vertical stack includes a first nanosheet, a second nanosheet above the first nanosheet and a third nanosheet above the second nanosheet, wherein each of the first, second and third nanosheets is defined by an upper surface, a left surface, a right surface, and a bottom surface in a cross-sectional view;
a second vertical stack of nanosheet channel regions spaced a distance from the first vertical stack, wherein the second vertical stack includes a fourth nanosheet, a fifth nanosheet above the fourth nanosheet and a sixth nanosheet above the fifth nanosheet wherein each of the fourth, fifth and sixth nanosheets is defined by an upper surface, a left surface, a right surface, and a bottom surface in the cross-sectional view; and
a dielectric wall in the distance,
wherein a silicon oxide layer has a portion extending from interfacing the right surface of each of the first, second and third nanosheets to interfacing the dielectric wall and a portion extending from interfacing the left surface of each of the fourth, fifth and sixth nanosheets to interfacing the dielectric wall, and
wherein a high-k dielectric layer is formed on each of the upper surface, lower surface and left surface of each of the first, second and third nanosheets, and the high-k dielectric layer is formed on each of the upper surface, lower surface and right surface of each of the fourth, fifth and sixth nanosheets, and the high-k dielectric layer is formed on the silicon oxide layer.

11. The semiconductor device of claim 10, wherein the high-k dielectric layer directly interfaces the silicon oxide layer.

12. The semiconductor device of claim 11, wherein the high-k dielectric layer directly interfaces the dielectric wall.

13. The semiconductor device of claim 10, wherein portions of the silicon oxide layer extending from the right surface of each of the first, second and third nanosheets extend less than or equal to about 6 nanometers.

14. The semiconductor device of claim 10, wherein an interfacial layer interposes the high-k dielectric layer and each of the upper surface, lower surface and left surface of each of the first, second and third nanosheets, and the interfacial layer interposes the high-k dielectric layer and each of the upper surface, lower surface and right surface of each of the fourth, fifth and sixth nanosheets.

15. The semiconductor device of claim 14, wherein the interfacial layer interfaces the silicon oxide layer.

16. A method for manufacturing a semiconductor device, comprising:
forming a stack of nanosheet channel layers extending in a first direction;
forming a dummy gate over the stack, the dummy gate extending in a second direction;
etching a first trench in the dummy gate and filling the first trench with a dielectric material to form a dielectric wall;
after removing the dummy gate to form an opening, forming a metal gate structure including a high-k gate dielectric layer and a metal layer over the high-k gate dielectric layer in the opening and the metal gate structure engaging each nanosheet channel layer of the stack of nanosheet channel layers; and
etching a second trench in the metal gate structure; and
filling the second trench with isolation material to form an isolation feature.

17. The method as claimed in claim 16, wherein the etching the first trench exposes a sidewall of the stack of nanosheet channel layers.

18. The method as claimed in claim 16, wherein etching the first trench forms the first trench to a first depth and etching the second trench includes etching the second trench to a second depth, the second depth greater than the first depth.

19. The method as claimed in claim 16, further comprising, forming a third trench, wherein the third trench extends through the dielectric wall.

20. The method as claimed in claim 19, wherein forming the third trench forms the third trench to a first depth, etching the second trench forms the second trench to the first depth. and etching the first trench forms the first trench to a second depth less than the first depth.
